(19) United States
(12) Patent Application Publication
(10) Pub. No.: US 2026/0182663 A1
(43) Pub. Date: Jul. 2, 2026

(54) AEROSOL GENERATING DEVICE

(71) Applicant: KT&G CORPORATION, Daejeon (KR)

(72) Inventors: Dongsung KIM, Daejeon (KR); Youngbum KWON, Daejeon (KR); Yonghwan KIM, Daejeon (KR); Hwikyeong AN, Daejeon (KR)

(73) Assignee: KT&G CORPORATION, Daejeon (KR)

(21) Appl. No.: 19/332,151

(22) Filed: Sep. 18, 2025

(30) Foreign Application Priority Data
Dec. 31, 2024 (KR) 10-2024-0202571

(51) Int. Cl. A24F 40/51; A24F 40/10; A24F 40/20; A24F 40/30; A24F 40/465; A24F 40/485; A24F 40/53; A24F 40/57; A24F 40/65

(52) U.S. Cl. CPC A24F 40/51; A24F 40/20; A24F 40/465; A24F 40/53; A24F 40/57; A24F 40/10; A24F 40/30; A24F 40/485; A24F 40/65

(57) ABSTRACT

An aerosol generating device includes a housing including an insertion space accommodating an aerosol generating article, a heater configured to heat the aerosol generating article accommodated in the insertion space, and one or more support portions disposed in an upper portion of the heater, at least partially movable in a first direction facing the insertion space or in a second direction away from the insertion space, and configured to support the aerosol generating article disposed the insertion space, wherein a value of current flowing through the one or more support portions changes in response to a change in a state of the insertion space.

### CROSS-REFERENCE TO RELATED APPLICATION

This application is based on and claims priority under 35 U.S.C. § 119 to Korean Patent Application No. 10-2024-0202571, filed on Dec. 31, 2024, in the Korean Intellectual Property Office, the disclosure of which is incorporated by reference herein in its entirety.

### BACKGROUND

### 1. Field

Various embodiments relate to an aerosol generating device, and more particularly, to an aerosol generating device capable of supporting various aerosol generating articles and simultaneously detecting types and states of the aerosol generating articles.

### 2. Description of the Related Art

Recently, the demand for alternative methods for overcoming the shortcomings of general cigarettes has increased. For example, there is an increasing demand for a system for generating aerosols by heating a cigarette or an aerosol generating material by using an aerosol generating device, rather than by burning cigarettes. Accordingly, research on heating-type aerosol generating devices has been actively conducted.

On the other hand, in the case of aerosol generating devices used by inserting a cigarette (hereinafter, a stick or aerosol generating article may be used in the same meaning as a cigarette) thereinto, various types of cigarettes may be inserted into aerosol generating devices. In addition, even within the same type of cigarettes, deviations may occur during the manufacturing process and states of cigarettes may vary with the peripheral environment. That is, whenever aerosol generating devices are used, cigarettes inserted into aerosol generating devices may vary depending on various criteria. Accordingly, researches have been conducted into a technology for appropriately optimizing an aerosol generating device for a currently inserted cigarette whenever the aerosol generating device is used.

### SUMMARY

In the case of an aerosol generating device used by inserting an aerosol generating article thereinto, it is necessary to support or fix the aerosol generating article inserted into the device. In order to fix the aerosol generating article, generally, a rigid supporting element may be used.

In this regard, when an aerosol generating article manufactured to be larger than a predetermined design dimension is inserted into the aerosol generating device, the aerosol generating article may be crushed by the supporting element. Conversely, when an aerosol generating article manufactured to be smaller than the predetermined design dimension is inserted into the aerosol generating device, the support element may not support the aerosol generating article, or even when supports the aerosol generating article, the support element may not support the aerosol generating article firmly, which causes the aerosol generating article to move slightly while using the aerosol generating device.

Such a problem may deteriorate the user's taste of smoking when a user inhales an aerosol, or cause discomfort to the user. Therefore, there is a need for a supporting element capable of firmly supporting the inserted aerosol generating article regardless of the state of the inserted aerosol generating article without being affected by the deviation of the aerosol generating article.

Embodiments provide an aerosol generating device with a support portion capable of supporting various aerosol generating articles.

In addition, embodiments provide an aerosol generating device capable of detecting the type and state of an aerosol generating article through a support portion.

The technical problems of the present disclosure are not limited to the above-described description, and other technical problems may be clearly understood by one of ordinary skill in the art from the embodiments to be described hereinafter.

Additional aspects will be set forth in part in the description which follows and, in part, will be apparent from the description, or may be learned by practice of the presented embodiments of the disclosure.

According to an embodiment, an aerosol generating device includes a housing including an insertion space accommodating an aerosol generating article, a heater configured to heat the aerosol generating article accommodated in the insertion space, and one or more support portions disposed in an upper portion of the heater, at least partially movable in a first direction facing the insertion space or in a second direction away from the insertion space, and configured to support the aerosol generating article disposed the insertion space, wherein a value of current flowing through the one or more support portions changes in response to a change in a state of the insertion space.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an aerosol generating device according to an embodiment;

FIG. 2A illustrates an aerosol generating device according to an embodiment;

FIG. 2B illustrates an aerosol generating device according to an embodiment;

FIG. 3 illustrates an aerosol generating device according to an embodiment;

FIG. 4 is a cross-sectional view of an aerosol generating device according to an embodiment;

FIGS. 5A to 5C are cross-sectional views illustrating examples of support portions applied to an aerosol generating device according to embodiments;

FIGS. 6A and 6B are cross-sectional views illustrating examples of contact members of a support portion in contact with an aerosol generating article;

FIGS. 7A to 7C are cross-sectional views illustrating operation states of a support portion applied to an aerosol generating device according to an embodiment;

FIGS. 8A to 8C are cross-sectional views illustrating various numbers of support portions disposed in an aerosol generating device in a circumferential direction of an insertion space according to the embodiments;

FIGS. 9A and 9B are cross-sectional views illustrating an aerosol generating article with different lengths of identifiers surrounding an outer circumferential surface inserted into an aerosol generating device according to embodiments;

FIG. 10 is a cross-sectional view of an aerosol generating device according to another embodiment to which a plurality of support portions disposed in a longitudinal direction of an insertion space are applied;

FIG. 11 is a cross-sectional perspective view illustrating an aerosol generating device according to another embodiment in which an airflow passage is formed between support portions disposed in a circumferential direction of an insertion space;

FIGS. 12A and 12B are cross-sectional views illustrating an operation state of an aerosol generating device while an aerosol generating article is inserted into the aerosol generating device according to another embodiment;

FIG. 13 is a diagram illustrating a heating profile that changes with the type of aerosol generating article inserted into an aerosol generating device according to another embodiment;

FIGS. 14A and 14B are respectively diagrams illustrating a first heating profile and a second heating profile that change according to a first diameter and a second diameter of aerosol generating articles inserted into an aerosol generating device according to another embodiment;

FIG. 15 is a diagram illustrating a heating profile that changes with a state of an aerosol generating article inserted into an aerosol generating device according to another embodiment; and

FIG. 16 is a diagram illustrating an aerosol generating device according to another embodiment to which a heating support portion is applied and a filter rod of an aerosol generating article heated by the heating support portion.

### DETAILED DESCRIPTION

Hereinafter, the embodiments disclosed in the present specification will be described in detail with reference to the accompanying drawings. The same or similar elements are denoted by the same reference numerals even though they are depicted in different drawings, and redundant descriptions thereof will be omitted. With regard to the description of the drawings, similar reference numerals may be used to refer to similar or related elements.

In the following description, with respect to constituent elements used in the following description, the suffixes “module” and “unit” are used only in consideration of facilitation of description, and do not have mutually distinguished meanings or functions. As used herein, the suffix “module” or “unit” may include a unit implemented in hardware, software, or firmware, and may be used interchangeably with other terms, for example, “logic,” “logic block,” “part,” or “circuitry.” A “module” or a “unit” may be a single integral component, or a minimum unit or part thereof, adapted to perform one or more functions. For example, the “module” or the “unit” may be implemented in the form of an application-specific integrated circuit (ASIC).

In addition, in the following description of the embodiments disclosed in the present specification, a detailed description of known functions and configurations incorporated herein will be omitted when the same may make the subject matter of the embodiments disclosed in the present specification rather unclear. In addition, the accompanying drawings are provided only for a better understanding of the embodiments disclosed in the present specification and are not intended to limit the technical ideas disclosed in the present specification. Therefore, it should be understood that the accompanying drawings include all modifications, equivalents, and substitutions within the scope and spirit of the present disclosure.

It will be understood that although the terms “first”, “second”, etc., may be used herein to describe various components, these components should not be limited by these terms. These terms are only used to distinguish one component from another component.

It will be understood that when a component is referred to as being “connected to” or “coupled to” another component, it may be directly connected to or coupled to another component, or intervening components may be present. On the other hand, when a component is referred to as being “directly connected to” or “directly coupled to” another component, there are no intervening components present.

As used herein, the singular form is intended to include the plural forms as well, unless the context clearly indicates otherwise.

Embodiments as set forth herein may be implemented as software including one or more instructions that are stored in a storage medium (e.g., a memory 17) that is readable by a machine (e.g., the aerosol-generating device 1). For example, a processor (e.g., the controller 12) of the machine (e.g., the aerosol-generating device 1) may invoke at least one of the one or more instructions stored in the storage medium, and may execute the same. This allows the machine to be operated to perform at least one function according to the at least one instruction invoked. The one or more instructions may include code generated by a compiler or code executable by an interpreter. The machine-readable storage medium may be provided in the form of a non-transitory storage medium. Here, the term “non-transitory” simply means that the storage medium is a tangible device, and does not include a signal (e.g., an electromagnetic wave), but this term does not differentiate between where data is semi-permanently stored in the storage medium and where the data is temporarily stored in the storage medium.

In the present disclosure, the directions of the aerosol-generating device 1 may be defined based on the orthogonal coordinate system. In the orthogonal coordinate system, the x-axis direction may be defined as a leftward-rightward direction of the aerosol-generating device 1. The y-axis direction may be defined as a forward-backward direction of the aerosol-generating device 1. The z-axis direction may be defined as an upward-downward direction of the aerosol-generating device 1.

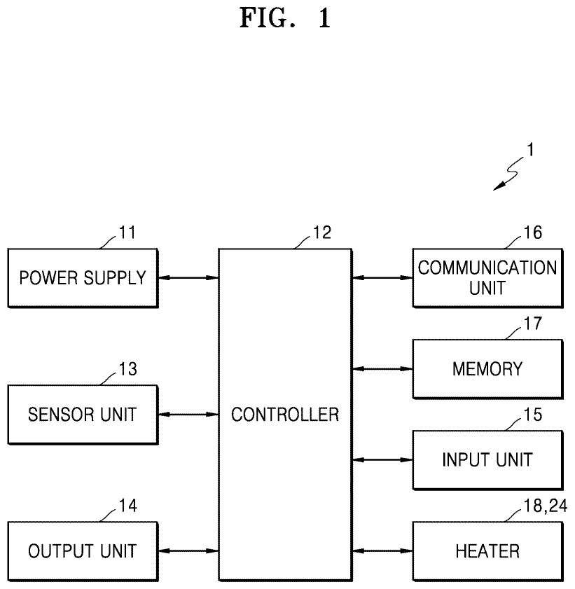

FIG. 1 is a block diagram of an aerosol-generating device according to an embodiment.

According to one embodiment, the aerosol-generating device 1 may include a power supply 11, a controller 12, a sensor unit 13, an output unit 14, an input unit 15, a communication unit 16, a memory 17, and/or a heater 18 and 24. However, the components included in the aerosol-generating device 1 are not limited to those shown in FIG. 1. That is, it will be understood by those skilled in the art related to the present embodiment that some of the components shown in FIG. 1 may be omitted or new components may be further included depending on the design of the aerosol-generating device 1.

According to one embodiment, the sensor unit 13 may detect the state of the aerosol-generating device 1 or the state of the surroundings of the aerosol-generating device 1, and may transmit the detected information to the controller 12. For example, the sensor unit 13 may include a temperature sensor, a puff sensor, an insertion detection sensor, a reuse detection sensor, an overly moist state detection sensor, a cigarette identification sensor, a cartridge detection sensor, a cap detection sensor, and/or a movement detection sensor. Meanwhile, the sensor unit 13 may further include various sensors, such as a liquid residual quantity sensor for detecting the residual quantity of liquid in the cartridge and an immersion sensor for detecting immersion of the aerosol-generating device 1.

According to one embodiment, the temperature sensor may detect a temperature to which the heater 18 and 24 is heated. The aerosol-generating device 1 may include a separate temperature sensor for detecting the temperature of the heater 18 and 24, or the heater 18 and 24 itself may serve as a temperature sensor. In an example, the temperature sensor may be used to measure impedance for the heater 18. The impedance for the heater 18 may correlate with the temperature of the heater 18. The temperature sensor may measure current and/or voltage applied to the heater 18 (or an induction coil). The impedance for the heater 18 may be obtained based on the measured current and/or voltage. The controller 12 may estimate the temperature of the heater 18 based on the obtained impedance.

In an example, the temperature sensor may include a resistance element (e.g., a thermistor), the resistance value of which varies in response to changes in the temperature of the heater 18 and 24. The temperature sensor may output a signal corresponding to the resistance value of the resistance element, and the controller 12 may determine the temperature of the heater 18 and 24 and/or a change in the temperature of the heater 18 and 24 based on the signal corresponding to the resistance value.

In another example, the temperature sensor may include a sensor that detects the resistance value of the heater 18 and 24. The temperature sensor may output a signal corresponding to the resistance value of the heater 18 and 24, and the controller 12 may determine the temperature of the heater 18 and 24 and/or a change in the temperature of the heater 18 and 24 based on the signal corresponding to the resistance value.

According to one embodiment, the temperature sensor may detect the temperature of the power supply 11. The temperature sensor may be disposed adjacent to the power supply 11. For example, the temperature sensor may be attached to one surface of the power supply 11 (e.g., a battery) and/or may be mounted on one surface of a printed circuit board. In an example, the aerosol-generating device 1 may include a power supply protection circuit module (PCM), and the temperature sensor may be disposed adjacent to the power supply 11 together with the power supply protection circuit module.

According to one embodiment, the temperature sensor may be disposed in a housing (not shown) of the aerosol-generating device 1 to detect the internal temperature of the housing (not shown).

According to one embodiment, the puff sensor may detect a user's puff.

In an example, the puff sensor may include a pressure sensor. The pressure sensor may output a signal corresponding to the internal pressure of the aerosol-generating device 1, and the controller 12 may determine the user's puff based on the signal corresponding to the internal pressure. Here, the internal pressure of the aerosol-generating device 1 may correspond to the pressure of an airflow path through which gas flows. The puff sensor may be disposed corresponding to the airflow path through which gas flows in the aerosol-generating device 1.

In another example, the puff sensor may include a temperature sensor. When the user's puff occurs, temperature drop may temporarily occur in the airflow path, a space into which an aerosol-generating article is inserted (hereinafter referred to as an “insertion space”), and the heater 18 and 24. The controller 12 may determine the user's puff based on a signal corresponding to the temperature of the airflow path output from the temperature sensor.

In still another example, the puff sensor may include both a pressure sensor and a temperature sensor. In this case, the temperature sensor may measure temperature used to calibrate the internal pressure measured by the pressure sensor. In one example, the puff sensor may calibrate a signal corresponding to the internal pressure based on the temperature measured by the temperature sensor, and may output the calibrated signal. In another example, the puff sensor may output a signal corresponding to the temperature measured by the temperature sensor and a signal corresponding to the internal pressure measured by the puff sensor. In this case, the controller 12 may receive the signals, and may calibrate the signal corresponding to the internal pressure based on the signal corresponding to the temperature.

In still another example, the puff sensor may include a capacitance sensor. The capacitance sensor may also be called a cap sensor or a capacitive sensor. When the user's puff occurs, a temperature change and/or aerosol flow may occur in the insertion space of the aerosol-generating article, and accordingly, a dielectric constant in the insertion space may change. The controller 12 may determine the user's puff based on a signal corresponding to the dielectric constant in the insertion space output from the capacitance sensor.

The puff sensor is not limited to the examples described above, and may be implemented as various sensors for detecting the user's puff.

According to one embodiment, the insertion detection sensor may detect insertion and/or removal of the aerosol-generating article. The insertion detection sensor may be mounted adjacent to the insertion space. In addition, the insertion detection sensor may include any combination of the examples described above.

In an example, the insertion detection sensor may include a capacitance sensor. The capacitance sensor may include at least one conductor, and the at least one conductor may be disposed adjacent to the insertion space. When the aerosol-generating article is inserted into or removed from the insertion space, capacitance around the conductor may change. The controller 12 may determine insertion and/or removal of the aerosol-generating article based on a signal corresponding to the dielectric constant in the insertion space output from the capacitance sensor.

In another example, the insertion detection sensor may include an inductive sensor. The inductive sensor may include at least one coil, and the at least one coil may be disposed adjacent to the insertion space. If the aerosol-generating article (e.g., a wrapper of the aerosol-generating article) includes a conductor, when the aerosol-generating article is inserted into or removed from the insertion space, a change in magnetic field may occur around the coil through which current flows. The controller 12 may determine insertion and/or removal of the aerosol-generating article including a conductor based on the characteristics of the current output from or detected by the inductive sensor (e.g., frequency of alternating current, a current value, a voltage value, an inductance value, and an impedance value). Alternatively, a susceptor SUS or the like may be included in the aerosol-generating article (e.g., a medium portion of the aerosol-generating article). In this case, a change in magnetic field may also occur around the coil based on insertion or removal of the susceptor or the like into or from the insertion space, and the controller 12 may determine insertion and/or removal of the aerosol-generating article based on the characteristics of the current of the inductive sensor.

The insertion detection sensor is not limited to the examples described above, and may be implemented as various sensors (e.g., a proximity sensor) for detecting insertion and/or removal of the aerosol-generating article. In addition, the insertion detection sensor may include any combination of the examples described above. According to one embodiment, the insertion detection sensor may include a switch or the like for detecting pressing by the aerosol-generating article.

According to one embodiment, the reuse detection sensor may detect whether the aerosol-generating article is being reused. In an example, the reuse detection sensor may be a color sensor for detecting the color of the aerosol-generating article. If the aerosol-generating article is used by the user, a change in the color of a portion of the wrapper may occur due to the generated aerosol or heating. The color sensor may output a signal corresponding to an optical characteristic (e.g., wavelength of light) corresponding to the color of the wrapper based on the light reflected from the wrapper. When a change in the color of a portion of the wrapper is detected, the controller 12 may determine that the aerosol-generating article inserted into the insertion space has already been used.

According to one embodiment, the overly moist state detection sensor may detect whether the aerosol-generating article is in an overly moist state. For example, the overly moist state detection sensor may include a capacitance sensor. The capacitance sensor may include at least one conductor disposed adjacent to the insertion space. The controller 12 may determine whether the aerosol-generating article is in an overly moist state based on the level of a signal corresponding to the dielectric constant or the like output from the capacitance sensor. In an example, the controller 12 may check a level range within which the level of the signal is included based on a look-up table, and may determine the moisture content of the aerosol-generating article based on the checked level range.

According to one embodiment, the cigarette identification sensor may detect whether the aerosol-generating article is authentic and/or may detect the type of the aerosol-generating article.

In an example, the cigarette identification sensor may include an optical sensor for detecting an identification material (or an identification mark) located on the outer surface (e.g., the wrapper) of the aerosol-generating article. The optical sensor may radiate light toward the identification material (or the identification mark) of the aerosol-generating article, and may detect whether the aerosol-generating article is authentic and/or may detect the type of the aerosol-generating article based on the reflected light. For example, the identification material may include a material (i.e., a luminous material) that emits light of a specific wavelength band based on the light radiated thereto. The controller 12 may determine whether the aerosol-generating article is authentic and/or may determine the type of the aerosol-generating article based on the range of the wavelength.

In another example, the cigarette identification sensor may include a capacitance sensor. The dielectric constant in the insertion space may vary depending on the type of the aerosol-generating article inserted into the insertion space. The controller 12 may determine whether the aerosol-generating article is authentic and/or may determine the type of the aerosol-generating article based on a signal corresponding to the dielectric constant or the like in the insertion space output from the capacitance sensor.

In still another example, the cigarette identification sensor may include an inductive sensor. If a conductor is included in the wrapper and/or inner portion (e.g., the medium portion) of the aerosol-generating article inserted into the insertion space, when the aerosol-generating article is inserted into the insertion space, the characteristics of the current detected by the inductive sensor (e.g., frequency of alternating current, a current value, a voltage value, an inductance value, and an impedance value) may vary depending on the type of the aerosol-generating article inserted into the insertion space. The controller 12 may determine whether the inserted aerosol-generating article is authentic and/or may determine the type of the inserted aerosol-generating article based on the characteristics of the current output from or detected by the inductive sensor.

The cigarette identification sensor is not limited to the examples described above, and may be implemented as various sensors for detecting whether the aerosol-generating article is authentic and/or detecting the type of the aerosol-generating article. In addition, the cigarette identification sensor may include any combination of the examples described above.

According to one embodiment, the cartridge detection sensor may detect mounting and/or removal of the cartridge. For example, the cartridge detection sensor may include an inductive sensor, a capacitance sensor, a resistance sensor, a Hall sensor (Hall IC), and/or an optical sensor.

According to one embodiment, the cap detection sensor may detect mounting and/or removal of the cap. For example, the cap detection sensor may include an inductive sensor, a capacitance sensor, a resistance sensor, a contact sensor, a Hall sensor (Hall IC), and/or an optical sensor. The cap may cover at least a portion of the cartridge mounted in or inserted into the aerosol-generating device 1 or may cover at least a portion of the housing of the aerosol-generating device 1. When the cap is mounted in or removed from the housing, the cap detection sensor may output a signal corresponding to mounting or removal, and the controller 12 may determine mounting or removal of the cap based on the signal corresponding to mounting or removal.

According to one embodiment, the movement detection sensor may detect movement of the aerosol-generating device 1. The movement detection sensor may be implemented as at least one of an acceleration sensor or a gyro sensor.

According to one embodiment, the sensor unit 13 may further include at least one of a humidity sensor, an air pressure sensor, a magnetic sensor, a position sensor (global positioning system (GPS)), or a proximity sensor in addition to the sensors described above. The functions of the sensors can be intuitively deduced by those skilled in the art from the names thereof, and thus detailed descriptions thereof may be omitted.

According to one embodiment, the output unit 14 may output information about the state of the aerosol-generating device 1 to provide the same to the user. The output unit 14 may include, but is not limited to, a display, a haptic unit, and/or a sound output unit. For example, information about the aerosol-generating device 1 may include a charging/discharging state of the power supply 11 of the aerosol-generating device 1, a preheating state of the heater 18 and 24, an insertion/removal state of the aerosol-generating article and/or the cartridge, a mounting/removal state of the cap, or a state in which the use of the aerosol-generating device 1 is restricted (e.g., detection of an abnormal object). The display may visually provide the information about the state of the aerosol-generating device 1 to the user. For example, the display may include a light-emitting diode (LED), a liquid crystal display panel (LCD), and an organic light-emitting diode panel (OLED). If the display includes a touchpad, the display may also be used as the input unit 15. The haptic unit may haptically provide the information about the aerosol-generating device 1 to the user. For example, the haptic unit may include a vibration motor, a piezoelectric element, and an electrical stimulation device. The sound output unit may audibly provide the information about the aerosol-generating device 1 to the user. For example, the sound output unit may convert an electrical signal into an acoustic signal and may output the acoustic signal to the outside.

According to one embodiment, the power supply 11 may supply power used for operation of the aerosol-generating device 1. The power supply 11 may include one or more batteries. The power supply 11 may supply power so that the heater 18 and 24 is heated. In addition, the power supply 11 may supply power necessary for operation of the other components included in the aerosol-generating device 1, such as the controller 12, the sensor unit 13, the output unit 14, the input unit 15, the communication unit 16, and the memory 17. The power supply 11 may be a rechargeable battery or a disposable battery. For example, the power supply 11 may be a lithium polymer (LiPoly) battery without being limited thereto. The power supply 11 may be a replaceable (separation-type) battery (hereinafter referred to as a “removable battery”). The removable battery may be mounted in a battery accommodation portion provided in the aerosol-generating device 1 or may be removed from the battery accommodation portion. The removable battery may be charged in a wired and/or wireless manner.

According to one embodiment, the heater 18 and 24 may receive power from the power supply 11 to heat the aerosol-generating article (e.g., a cigarette) and/or a medium and/or an aerosol-generating substance in the cartridge. The aerosol-generating device 1 may include a heater 18 for heating the aerosol-generating article and/or a cartridge heater 24 for heating the cartridge (i.e., a solid and/or liquid medium).

According to one embodiment, the heater 18 and 24 may be an electro-resistive heater. For example, the electro-resistive heater may include an electrically resistive material such as a metal or a metal alloy including titanium, zirconium, tantalum, platinum, nickel, cobalt, chromium, hafnium, niobium, molybdenum, tungsten, tin, gallium, manganese, iron, copper, stainless steel, and nichrome. The electro-resistive heater may be implemented as a metal wire, a metal plate having an electrically conductive track disposed thereon, or a ceramic heating element.

According to one embodiment, the heater 18 and 24 may be an induction heater. For example, the induction heater may include a susceptor that generates heat through a magnetic field. A magnetic field may be generated by an induction coil by alternating current flowing through the induction coil. The magnetic field may pass through the heater, and an eddy current may be generated in the susceptor. The susceptor may be heated based on generation of the eddy current. According to one embodiment, the susceptor may be included in the inner portion (e.g., the medium portion) of the aerosol-generating article. In this case, the susceptor included in the inner portion of the aerosol-generating article may also be heated by the induction coil.

The heater 18 and 24 is not limited to the examples described above, and may include or be replaced with various heating methods, structures, and components for heating the aerosol-generating article and/or the cartridge.

According to one embodiment, the input unit 15 may receive information input from the user. For example, the input unit 15 may include a touch panel, a button, a keypad, a dome switch, a jog wheel, and a jog switch.

According to one embodiment, the memory 17 may be hardware storing various pieces of data processed in the aerosol-generating device 1. The memory 17 may store data processed and to be processed by the controller 12. For example, the memory 17 may include at least one type of storage medium among a flash memory type memory, a hard disk type memory, a multimedia card micro type memory, a card type memory (e.g., SD or XD memory), a random access memory (RAM), a static random access memory (SRAM), a read-only memory (ROM), an electrically erasable programmable read-only memory (EEPROM), a programmable read-only memory (PROM), a magnetic memory, a magnetic disk, and an optical disc. For example, the memory 17 may store data on an operation time of the aerosol-generating device 1, the maximum number of puffs, the current number of puffs, at least one temperature profile, and the user's smoking pattern.

According to one embodiment, the communication unit 16 may include at least one component for communication with other electronic devices (e.g., a portable electronic device). For example, the communication unit 16 may include a Bluetooth communication unit, a Bluetooth low energy (BLE) communication unit, a near-field communication unit, a wireless local area network (WLAN) communication unit, a Zigbee communication unit, an infrared data association (IrDA) communication unit, a Wi-Fi direct (WFD) communication unit, an ultra-wideband (UWB) communication unit, an Ant+ communication unit, a cellular network communication unit, an Internet communication unit, and a computer network (e.g., LAN or WAN) communication unit.

According to one embodiment, the controller 12 may control the overall operation of the aerosol-generating device 1. For example, the controller 12 may include at least one processor. The controller 12 may be implemented as an array of a plurality of logic gates or may be implemented as a combination of a general-purpose microcontroller unit (MCU) (or a microprocessor) and a memory in which a program executable by the MCU is stored. It will be understood by those skilled in the art that the controller may also be implemented as other forms of hardware.

According to one embodiment, the controller 12 may control the supply of power from the power supply 11 to the heater 18 and 24 to control the temperature of the heater 18 and 24. The controller 12 may control the temperature of the heater 18 and 24 and/or power supplied to the heater 18 and 24 based on the temperature of the heater 18 and 24 detected by the temperature sensor (e.g., the sensor unit 13). The controller 12 may control the temperature of the heater 18 and 24 and/or power supplied to the heater 18 and 24 based on the temperature profile and/or the power profile stored in the memory 17.

According to one embodiment, the controller 12 may control a power conversion circuit (not shown) electrically connected to the heater 18 and 24 and the power supply 11 to control power (e.g., voltage and/or current) supplied to the heater 18 and 24. For example, the power conversion circuit may include a DC/DC converter (e.g., a buck converter, a buck-boost converter, a boost converter, or a Zener diode) that converts power to be supplied to the heater 18 and 24 and a DC/AC converter (e.g., an inverter) that converts power to be supplied to the induction coil (not shown). The DC/AC converter may be implemented as a full-bridge circuit or a half-bridge circuit including a plurality of switching elements. For example, the power conversion circuit may include at least one switching element, such as a bipolar junction transistor (BJT) or a field effect transistor (FET).

According to one embodiment, the controller 12 may control the frequency and/or duty ratio of a current pulse input to at least one switching element of the power conversion circuit (not shown) to control the current and/or the voltage supplied to the heater 18 and 24. The duty ratio for the on/off operation of the switching element may correspond to a ratio of the voltage output from the power conversion circuit to the voltage output from the power supply 11.

According to one embodiment, the controller 12 may control power supplied to the heater 18 and 24 using at least one of a pulse width modulation (PWM) scheme or a proportional-integral-differential (PID) scheme. For example, the controller 12 may perform control using the PWM scheme such that a current pulse having a predetermined frequency and a predetermined duty ratio is supplied to the heater 18 and 24. The controller 12 may control the frequency and duty ratio of the current pulse to control power supplied to the heater 18 and 24. For example, the controller 12 may determine, based on the temperature profile, a target temperature to be controlled. The controller 12 may control power supplied to the heater 18 and 24 using the PID scheme, which is a feedback control scheme using a difference value between the temperature of the heater 18 and the target temperature, a value obtained by integrating the difference value with respect to time, and a value obtained by differentiating the difference value with respect to time.

According to one embodiment, the controller 12 may determine, based on the power profile, target power to be controlled. The controller 12 may control power supplied to the heater 18 and 24 so as to correspond to the preset target power over time.

According to one embodiment, the controller 12 may detect power supplied to the heater 18 and 24 to determine the user's puff. In more detail, the controller 12 may control power supplied to the heater 18 and 24 using the proportional-integral-differential (PID) scheme. When the user's puff occurs, temperature drop may temporarily occur in a space into which the aerosol-generating article is inserted (hereinafter referred to as an insertion space) and the heater 18 and 24. Accordingly, the power (or the current) supplied to the heater 18 and 24 may change during control of the power using the PID scheme. The controller 12 may determine the user's puff based on the change in the power controlled.

According to one embodiment, the controller 12 may prevent the heater 18 and 24 from overheating. For example, the controller 12 may control, based on the temperature of the heater 18 and 24 exceeding a preset limit temperature, operation of the power conversion circuit such that the amount of power supplied to the heater 18 and 24 is reduced or the supply of power to the heater 18 and 24 is interrupted.

According to one embodiment, the controller 12 may control charging/discharging of the power supply 11. For example, the controller 12 may check the temperature of the power supply 11 using the temperature sensor (e.g., the sensor unit 13). If the temperature of the power supply 11 is equal to or higher than a first limit temperature, the controller 12 may interrupt charging of the power supply 11. If the temperature of the power supply 11 is equal to or higher than a second limit temperature, the controller 12 may interrupt use of the power stored in the power supply 11 (e.g., discharging). The controller 12 may calculate the remaining amount of the power stored in the power supply 11. For example, the controller 12 may calculate the remaining capacity of the power supply 11 based on a voltage and/or current detection value of the power supply 11.

According to one embodiment, the controller 12 may control the supply of power to the heater 18 and 24 based on a result of the detection by the sensor unit 13.

According to one embodiment, the controller 12 may control the supply of power to the heater 18 and 24 based on insertion and/or removal of the aerosol-generating article into and/or from the insertion space. For example, upon determining that the aerosol-generating article has been inserted into the insertion space using the insertion detection sensor (e.g., the sensor unit 13), the controller 12 may perform control such that power is supplied to the heater 18 and 24. Upon determining that the aerosol-generating article has been removed from the insertion space using the insertion detection sensor (e.g., the sensor unit 13), the controller 12 may interrupt the supply of power to the heater 18 and 24. The controller 12 may determine that the aerosol-generating article has been removed from the insertion space when the temperature of the heater 18 and 24 is equal to or higher than a limit temperature or when the temperature change slope of the heater 18 and 24 is equal to or greater than a preset slope.

According to one embodiment, the controller 12 may control, based on the state of the aerosol-generating article, a power supply time and/or the amount of power supplied to the heater 18 and 24. For example, upon determining that the aerosol-generating article is in an overly moist state using the overly moist state detection sensor (e.g., the sensor unit 13), the controller 12 may increase a time during which power is supplied to the heater 18 and 24 (e.g., a preheating time).

According to one embodiment, the controller 12 may control the supply of power to the heater 18 and 24 based on whether the aerosol-generating article is being reused. For example, upon determining that the aerosol-generating article has already been used, the controller 12 may interrupt the supply of power to the heater 18 and 24.

According to one embodiment, the controller 12 may control the supply of power to the heater 18 and 24 based on whether the cartridge has been coupled and/or removed. For example, upon determining that the cartridge has been removed using the cartridge detection sensor (e.g., the sensor unit 13), the controller 12 may interrupt the supply of power to the heater 18 or 24 or may perform control such that power is not supplied to the heater 18 and 24.

According to one embodiment, the controller 12 may control the supply of power to the heater 18 and 24 based on whether the aerosol-generating substance in the cartridge has been exhausted. For example, upon determining that the temperature of the heater 18 and 24 exceeds a limit temperature during preheating of the heater 18 and 24 (i.e., in the preheating section), the controller 12 may determine that the aerosol-generating substance in the cartridge has been exhausted. Upon determining that the aerosol-generating substance in the cartridge has been exhausted, the controller 12 may interrupt the supply of power to the heater 18 and 24.

According to one embodiment, the controller 12 may control the supply of power to the heater 18 and 24 based on whether use of the cartridge is possible. For example, upon determining, based on data stored in the memory 17, that the current number of puffs is equal to or greater than the maximum number of puffs set for the cartridge, the controller 12 may determine that use of the cartridge is impossible. Alternatively, when a total time period during which the heater 18 and 24 is heated is equal to or longer than a preset maximum time period or when the total amount of power supplied to the heater 18 and 24 is equal to or greater than a preset maximum amount of power, the controller 12 may determine that use of the cartridge is impossible. In this case, the controller 12 may interrupt the supply of power to the heater 18 or 24 or may perform control such that power is not supplied to the heater 18 and 24.

According to one embodiment, the controller 12 may control the supply of power to the heater 18 and 24 based on the user's puff. For example, the controller 12 may determine whether a puff occurs and/or the intensity of a puff using the puff sensor (e.g., the sensor unit 13). When the number of puffs reaches a preset maximum number of puffs and/or when no puff is detected for a preset time period or longer, the controller 12 may interrupt the supply of power to the heater 18 and 24. When a puff is detected, the controller 12 may control the supply of power to the heater 18 and 24.

According to one embodiment, the controller 12 may control the supply of power to the heater 18 and 24 based on whether the aerosol-generating article (or the cartridge) is authentic and/or the type of the aerosol-generating article (or the cartridge). For example, the controller 12 may determine whether the aerosol-generating article is authentic and/or may determine the type of the aerosol-generating article using the cigarette identification sensor (e.g., the sensor unit 13). In an example, upon determining that the aerosol-generating article (or the cartridge) is inauthentic, the controller 12 may interrupt the supply of power to the heater 18 and 24. Upon determining that the aerosol-generating article (or the cartridge) is authentic, the controller 12 may control (e.g., commence) the supply of power to the heater 18 and 24. In another example, the controller 12 may control the supply of power to the heater 18 and 24 differently depending on the type of the aerosol-generating article (or the cartridge). In more detail, upon determining that the aerosol-generating article (or the cartridge) is a first aerosol-generating article (or a first cartridge), the controller 12 may control the temperature of the heater 18 and 24 and/or power based on a first temperature profile (or a first power profile), and upon determining that the aerosol-generating article (or the cartridge) is a second aerosol-generating article (or a second cartridge), the controller 12 may control the temperature of the heater 18 and 24 and/or power based on a second temperature profile (or a second power profile).

According to one embodiment, the controller 12 may control the output unit 14 based on a result of detection by the sensor unit 13. For example, when the number of puffs counted using the puff sensor (e.g., the sensor unit 13) reaches a preset number, the controller 12 may control the output unit 14 to visually, haptically, and/or audibly provide information that operation of the aerosol-generating device 1 will end soon. For example, the controller 12 may control the output unit 14 to visually, haptically, and/or audibly provide information about the temperature of the heater 18 and 24.

According to one embodiment, based on occurrence of a predetermined event, the controller 12 may store a history of the corresponding event in the memory 17 and may update the history. For example, the event may include events performed in the aerosol-generating device 1, such as detection of insertion of the aerosol-generating article, commencement of heating of the aerosol-generating article, detection of puff, termination of puff, detection of overheating of the heater 18 and 24, detection of application of overvoltage to the heater 18 and 24, termination of heating of the aerosol-generating article, on/off operation of the aerosol-generating device 1, commencement of charging of the power supply 11, detection of overcharging of the power supply 11, and termination of charging of the power supply 11. For example, the history of the event may include the occurrence date and time of the event and log data corresponding to the event. For example, when the predetermined event is detection of insertion of the aerosol-generating article, the log data corresponding to the event may include data on a value detected by the insertion detection sensor (e.g., the sensor unit 13). For example, when the predetermined event is detection of overheating of the heater 18 and 24, the log data corresponding to the event may include data on the temperature of the heater 18 and 24, the voltage applied to the heater 18 and 24, and the current flowing through the heater 18 and 24.

According to one embodiment, the controller 12 may control the communication unit 16 to form a communication link with an external device such as a user's mobile terminal.

According to one embodiment, upon receiving data on authentication from an external device via the communication link, the controller 12 may release restriction on use of at least one function (e.g., a heating function) of the aerosol-generating device 1. For example, the data on authentication may include the user's birthday, an identification number uniquely identifying the user, and whether authentication is completed by the user.

According to one embodiment, the controller 12 may transmit data on the state of the aerosol-generating device 1 (e.g., remaining capacity of the power supply 11 and operation mode) to the external device via the communication link. The transmitted data may be output through a display or the like of the external device.

According to one embodiment, upon receiving a request to search for the location of the aerosol-generating device 1 from the external device via the communication link, the controller 12 may control the output unit 14 to perform an operation corresponding to location search. For example, the controller 12 may perform control such that the haptic unit generates vibration or the display outputs objects corresponding to location search and termination of search.

According to one embodiment, upon receiving firmware data from the external device via the communication link, the controller 12 may perform firmware update.

According to one embodiment, the controller 12 may transmit data on a value detected by the at least one sensor unit 13 to an external server (not shown) via the communication link, and may receive, from the server, and store a learning model generated by learning the detected value through machine learning such as deep learning. The controller 12 may perform the operation of determining the user's puff pattern and the operation of generating the temperature profile using the learning model received from the server.

Although not shown in FIG. 1, the aerosol-generating device 1 may further include a power supply protection circuit. The power supply protection circuit may include at least one switching element, and may block an electric path to the power supply 11 in response to overcharging and/or overdischarging of the power supply 11. The aerosol-generating device 1 may further include a connection interface such as a universal serial bus (USB) interface, and may be connected to other external devices through the connection interface to transmit and receive information or charge the power supply 11.

The aerosol-generating article mentioned in the present disclosure may include at least one aerosol-generating rod (e.g., a medium portion) and at least one filter rod. The heater 18 may be disposed to correspond to the at least one aerosol-generating rod, and may be designed differently depending on the arrangement order and/or positions of the aerosol-generating rod and the filter rod. The aerosol-generating rod may contain at least one of nicotine, an aerosol-generating substance, and an additive. For example, the aerosol-generating substance may include glycerin (e.g., vegetable glycerin (VG)) and/or propylene glycol (PG) and may also include various other substances. For example, the additive may include a flavoring agent and/or an organic acid and may also include various other substances. For example, the aerosol-generating rod may include an aerosol-generating substrate (e.g., a sheet) impregnated with a liquid non-tobacco substance (e.g., an aerosol-generating substance and/or nicotine) and/or may contain a solid tobacco substance (e.g., leaf tobacco and reconstituted tobacco). The tobacco substance may be contained in the aerosol-generating rod in various forms, such as shredded tobacco, granules, and powder. According to one embodiment, the additive of the aerosol-generating rod may include an alkaline substance. Based on the alkaline substance, nicotine contained in the tobacco substance in the aerosol-generating rod may have an alkaline pH (e.g., pH 7.0 or higher). In this case, freebase nicotine may be released from the aerosol-generating rod even at a low temperature. According to one embodiment, the aerosol-generating rod may include two or more aerosol-generating rods, each of which may contain a tobacco substance and/or a non-tobacco substance. Meanwhile, although not shown, the at least one aerosol-generating rod and the at least one filter rod may individually and/or integrally be wrapped by at least one wrapper. In the present disclosure, the aerosol-generating article may be referred to as a stick.

The cartridge mentioned in the present disclosure may contain an aerosol-generating substance having any one state among a liquid state, a solid state, a gaseous state, and a gel state. The aerosol-generating substance may include a liquid composition. For example, the liquid composition may be a liquid containing a tobacco-containing substance including a volatile tobacco flavor component or may be a liquid containing a non-tobacco substance. Meanwhile, the cartridge may include a storage part that contains the aerosol-generating substance and/or a liquid delivery part that is impregnated with (contains) the aerosol-generating substance. For example, the liquid delivery part may include a wick formed of, e.g., cotton fiber, ceramic fiber, glass fiber, or porous ceramic. The cartridge heater 24 may be included in the cartridge in a coil-shaped structure surrounding (or wound around) the liquid delivery part or a structure contacting one side of the liquid delivery part. Alternatively, the cartridge heater 24 may be included in the aerosol-generating device 1, which is removable from the cartridge.

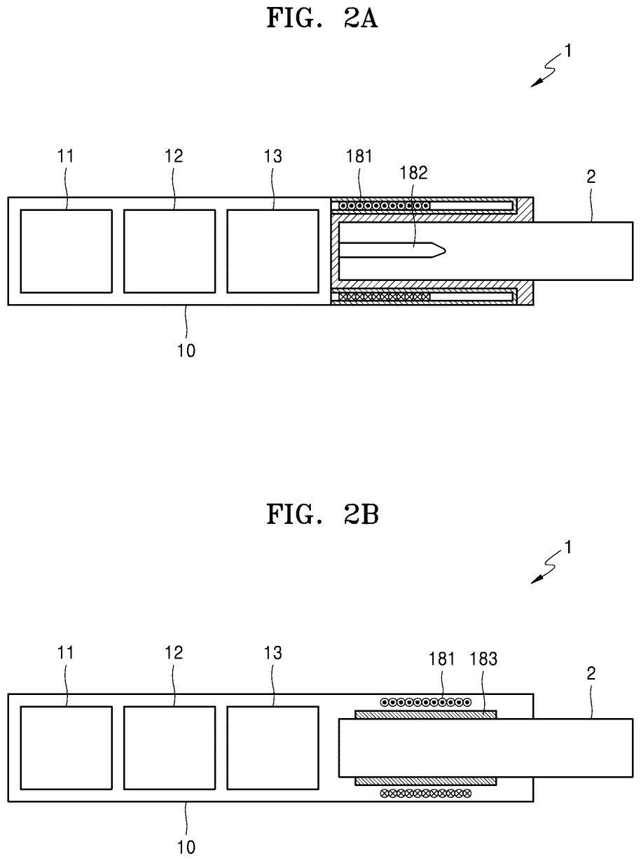

FIG. 2a shows an aerosol-generating device 1 according to an embodiment. FIG. 2b shows an aerosol-generating device 1 according to an embodiment.

According to one embodiment, the aerosol-generating device 1 may include a housing 10, a power supply 11, a controller 12, a sensor unit 13, and/or a heater 182 and 183 (e.g., the heater 18 in FIG. 1). However, it will be understood by those skilled in the art related to the present embodiment that the components included in the aerosol-generating device 1 are not limited to those shown in FIG. 2a or FIG. 2b and that some of the components may be omitted or new components may be further included. The aerosol-generating device 1 shown in FIG. 2a may be referred to as an “internal heating-type” aerosol-generating device that heats the inner side of an aerosol-generating article 2. The aerosol-generating device 1 shown in FIG. 2b may be referred to as an “external heating-type” aerosol-generating device that heats the outer side of the aerosol-generating article 2. In the drawings below, a description of configurations identical to those shown in FIG. 1 will be omitted.

According to one embodiment, the housing 10 may provide a space that is open upwardly to allow the aerosol-generating article 2 to be inserted thereinto. In the present disclosure, the space that is open upwardly may be referred to as an insertion space. The insertion space may be formed so as to be depressed in the housing 10 to a predetermined depth so that at least a portion of the aerosol-generating article 2 may be inserted thereinto. The depth of the insertion space may be equal to or greater than the length of a region of the aerosol-generating article 2 in which an aerosol-generating substance and/or a medium is contained. The lower end of the aerosol-generating article 2 may be inserted into the housing 10, and the upper end of the aerosol-generating article 2 may protrude outside the housing 10. A user may inhale an aerosol while holding the externally exposed upper end of the aerosol-generating article 2 in the mouth.

According to one embodiment, the heater 182 and 183 may heat the aerosol-generating article 2.

Referring to FIG. 2a, the heater 182 may be an internal heating-type heater.

According to one embodiment, the internal heating-type heater may be elongated upwardly in the space into which the aerosol-generating article 2 is inserted (i.e., the insertion space). For example, as shown in the drawings, the internal heating-type heater may include a rod-shaped or needle-shaped heating element. Alternatively, the internal heating-type heater may include various other heating elements, such as a tubular heating element or a plate-shaped heating element. The internal heating-type heater may be inserted through the lower portion of the aerosol-generating article 2.

According to one embodiment, the internal heating-type heater may include an electro-resistive heater and/or an induction heater.

For example, the electro-resistive heater may include an electro-resistive material, which is provided on the inner side (e.g., in the cavity or on the inner surface) or outer side (e.g., on the outer surface) thereof, and may generate heat as current flows through the electro-resistive material. In this case, the electro-resistive heater may be electrically connected to the power supply 11, and may directly generate heat using current received from the power supply 11. Meanwhile, an induction coil 181 may be omitted.

For example, in the case of an induction heater, the aerosol-generating device 1 may include an induction coil 181 surrounding at least a portion of the internal heating-type heater (e.g., disposed outside the heater so as to correspond to the length of at least a portion of the heater). In this case, a magnetic flux concentrator may be further provided outside the induction coil 181 in order to increase efficiency of induction heating. The induction heater may include a susceptor, and may generate heat based on a magnetic field generated by the induction coil 181. According to one embodiment, the induction heater (e.g., the susceptor) (or a heater module including the same) may be disposed to be removable from the housing 10.

According to one embodiment, the heater 182 may be a multi-heater. The multi-heater may include a first heater and a second heater, and may be inserted into the aerosol-generating article 2. The first heater and the second heater may be disposed side by side in the longitudinal direction. The first heater and the second heater may operate as an electro-resistive heater and/or an induction heater, and may be heated sequentially or simultaneously. In this case, the first heater and the second heater may be disposed at positions corresponding to the positions of two or more aerosol-generating rods in the longitudinal direction, respectively. Alternatively, the first heater and the second heater may be disposed at positions corresponding to the positions of a first portion and a second portion of one aerosol-generating rod in the longitudinal direction, respectively. Meanwhile, if the heater 182 is an induction heater, the aerosol-generating device 1 may include a first induction coil and a second induction coil, and the first induction coil and the second induction coil may be disposed at positions corresponding to the positions of the first heater and the second heater in the longitudinal direction, respectively. Alternatively, the first heater and the second heater may be disposed at positions corresponding to the positions of a first portion and a second portion of one heater 182 in the longitudinal direction, respectively. In addition, three or more heaters and/or three or more induction coils may be included.

According to one embodiment, the susceptor may be disposed on (or included in) the inner side (e.g., the medium portion) of the aerosol-generating article 2. The susceptor included inside the aerosol-generating article 2 may be implemented to be heated based on a magnetic field generated by the induction coil 181.

Referring to FIG. 2b, the heater 183 may be an external heating-type heater.

According to one embodiment, the external heating-type heater may be elongated upwardly around the space into which the aerosol-generating article 2 is inserted (i.e., the insertion space). For example, the external heating-type heater may be disposed so as to surround at least a portion of the insertion space. In an example, the external heating-type heater may include a tube shape (e.g., a cylindrical shape) with a cavity formed therein. The external heating-type heater may alternatively include a shape including a cavity formed therein and surrounding the cavity. In this case, the external heating-type heater may be supported by a polyimide film. The heater supported by this film may be referred to as a film heater. The external heating-type heater may be disposed so as to surround at least a portion of the insertion space. The external heating-type heater may heat the outer side of the aerosol-generating article 2 inserted into the cavity.

According to one embodiment, the external heating-type heater may include an electro-resistive heater and/or an induction heater, and a description of configurations identical to those shown in FIG. 2a will be omitted. Meanwhile, in the case of an induction heater, the aerosol-generating device 1 may include an external heating-type heater implemented as a tubular susceptor and may include an induction coil 181 surrounding at least a portion of the external heating-type heater (e.g., disposed outside the heater so as to correspond to the length of at least a portion of the heater). In addition, the induction coil 181 may include a fan coil. Meanwhile, if the external heating-type heater is an electro-resistive heater, heat may be generated through current flow through the tubular electro-resistive heater (e.g., the film heater), and thus a separate induction coil 181 may be omitted. Meanwhile, a thermally insulating material may be disposed outside the external heating-type heater. Accordingly, the amount of heat emitted from the heater 183 in the radially outward direction and released outside the housing 10 may be reduced.

According to one embodiment, the heater 183 may be a multi-heater, and the first heater and the second heater may be disposed side by side in the longitudinal direction so as to surround at least a portion of the insertion space. The first heater and the second heater may operate as an electro-resistive heater and/or an induction heater, and may be heated sequentially or simultaneously. Meanwhile, if the heater 183 is an induction heater, the aerosol-generating device 1 may include a first induction coil and a second induction coil. The first induction coil and the second induction coil may be disposed at positions corresponding to the positions of the first heater and the second heater in the longitudinal direction, respectively. Alternatively, the first heater and the second heater may be disposed at positions corresponding to the positions of a first portion and a second portion of one heater 183 in the longitudinal direction, respectively.

Unlike the configuration shown in FIG. 2a or FIG. 2b, both the heater 182 in FIG. 2a and the heater 183 in FIG. 2b may be included in the aerosol-generating device 1. In this case, the heater 182 may heat the inner side of the aerosol-generating article 2, and the heater 183 may heat the outer side of the aerosol-generating article 2.

According to one embodiment, the aerosol-generating device 1 may be provided with an airflow channel through which air flows. For example, the housing 10 may include a structure (e.g., a hole) through which outside air may be introduced into the housing 10. The air introduced into the housing 10 may be introduced into the aerosol-generating article 2 through the lower end (i.e., upstream side) of the aerosol-generating article 2. An aerosol generated based on heating of the aerosol-generating article 2 may be inhaled into the user's oral cavity together with the introduced air through the upper end (i.e., downstream side) of the aerosol-generating article 2.

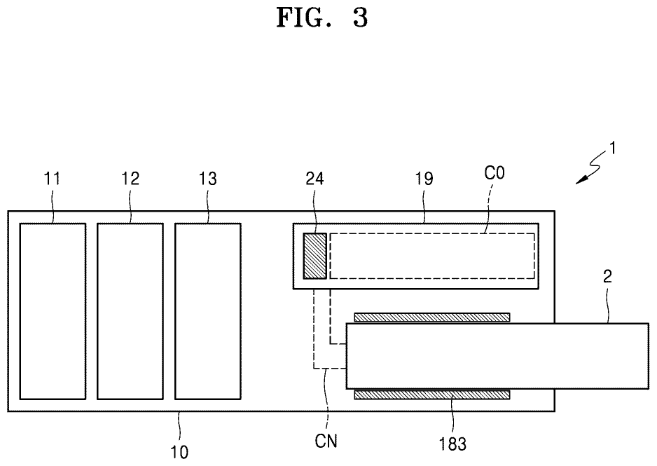

FIG. 3 shows an aerosol-generating device 1 according to an embodiment.

According to one embodiment, the aerosol-generating device 1 may include a housing 10, a power supply 11, a controller 12, a sensor unit 13, and/or a heater 183 and 24 (e.g., the heater 18 and 24 in FIG. 1). However, it will be understood by those skilled in the art related to the present embodiment that the components included in the aerosol-generating device 1 are not limited to those shown in FIG. 3 and that some of the components may be omitted or new components may be further included. In the drawings below, a description of configurations identical to those shown in FIG. 1 will be omitted.

According to one embodiment, the housing 10 may provide a space that is open upwardly to allow the aerosol-generating article 2 to be inserted thereinto (hereinafter referred to as an insertion space). The insertion space may be formed so as to be depressed in the housing 10 to a predetermined depth so that at least a portion of the aerosol-generating article 2 may be inserted thereinto. The lower end of the aerosol-generating article 2 may be inserted into the housing 10, and the upper end of the aerosol-generating article 2 may protrude outside the housing 10.

Unlike the configuration shown in the drawings, the cartridge 19 may provide an insertion space for receiving the aerosol-generating article 2. In this case, the insertion space may be formed so as to be depressed in the cartridge 19 to a predetermined depth so that at least a portion of the aerosol-generating article 2 may be inserted thereinto. The lower end of the aerosol-generating article 2 may be inserted into the cartridge 19, and the upper end of the aerosol-generating article 2 may protrude outside the cartridge 19. In this case, the aerosol-generating device 1 may not include the heater 183.

According to one embodiment, the depth of the insertion space may be equal to or greater than the length of a region of the aerosol-generating article 2 in which an aerosol-generating substance and/or a medium is contained. A user may inhale air while holding the externally exposed upper end of the aerosol-generating article 2 in the mouth.

According to one embodiment, the heater 183 may heat the aerosol-generating article 2. The heater 183 may be elongated upwardly around the space into which the aerosol-generating article 2 is inserted (i.e., the insertion space). In an example, the heater 183 may have a tube shape (e.g., a cylindrical shape) with a cavity formed therein. The heater 183 may include a shape including a cavity formed therein and surrounding the cavity. In this case, the heater 183 may be supported by a polyimide film. The heater supported by this film may be referred to as a film heater. The heater 183 may be disposed so as to surround at least a portion of the insertion space. The heater 183 may heat the outer side of the aerosol-generating article 2 inserted into the cavity. In the present disclosure, the heater 183 may be referred to as an external heating-type heater, which heats the outer side of the aerosol-generating article 2. Meanwhile, a thermally insulating material may be disposed outside the heater 183. Accordingly, the amount of heat emitted from the heater 183 in the radially outward direction and released outside the housing 10 may be reduced.

According to one embodiment, the heater 183 may include an electro-resistive heater and/or an induction heater.

For example, the electro-resistive heater may include an electro-resistive material, and may generate heat as current flows through the electro-resistive material. In this case, the electro-resistive heater may be electrically connected to the power supply 11, and may directly generate heat using current received from the power supply 11.

For example, in the case of an induction heater, the aerosol-generating device 1 may further include an induction coil (not shown) surrounding at least a portion of the heater 183 (e.g., disposed outside the heater 183 so as to correspond to the length of at least a portion of the heater 183). In this case, a magnetic flux concentrator may be further provided outside the induction coil (not shown) in order to increase efficiency of induction heating. The induction heater may include a susceptor, and may generate heat based on a magnetic field generated by the induction coil (not shown).

According to one embodiment, the heater 183 may be a multi-heater. The multi-heater may include a first heater and a second heater, and may be inserted into the aerosol-generating article 2. The first heater and the second heater may be disposed side by side in the longitudinal direction. The first heater and the second heater may operate as an electro-resistive heater and/or an induction heater, and may be heated sequentially or simultaneously. In this case, the first heater and the second heater may be disposed at positions corresponding to the positions of two or more aerosol-generating rods in the longitudinal direction, respectively. Alternatively, the first heater and the second heater may be disposed at positions corresponding to the positions of a first portion and a second portion of one aerosol-generating rod in the longitudinal direction, respectively. Meanwhile, if the heater 183 is an induction heater, the aerosol-generating device 1 may include a first induction coil and a second induction coil, and the first induction coil and the second induction coil may be disposed at positions corresponding to the positions of the first heater and the second heater in the longitudinal direction, respectively. Alternatively, the first heater and the second heater may be disposed at positions corresponding to the positions of a first portion and a second portion of one heater 183 in the longitudinal direction, respectively. In addition, three or more heaters and/or three or more induction coils may be included.

Unlike the configuration shown in the drawings, the aerosol-generating device 1 may not include the heater 183. The aerosol-generating article 2 may be directly or indirectly heated by the cartridge heater 24 or may not be substantially heated. Indirect heating may mean that the aerosol-generating article 2 is heated by receiving heat contained in the aerosol during the process in which the aerosol generated by the cartridge heater 24 passes through the aerosol-generating article 2. In this case, the aerosol-generating device 1 may be referred to as a non-heating-type (or indirect heating-type) aerosol-generating device. An additive such as an alkaline substance may be contained in the aerosol-generating rod of the aerosol-generating article 2. Based on the alkaline substance, nicotine contained in the aerosol-generating rod may have an alkaline pH (e.g., pH 7.0 or higher). This alkaline nicotine may flow to the user's oral cavity together with the aerosol introduced into the aerosol-generating article 2 from the cartridge 19 to be described later.

Unlike the configuration shown in the drawings, the heater 183 may include an internal heating-type heater. For example, the internal heating-type heater may include various heating elements, such as a rod-shaped heating element, a tubular heating element, a plate-shaped heating element, or a needle-shaped heating element. The internal heating-type heater may be inserted through the lower portion of the aerosol-generating article 2, and may be set to heat the inner side of the aerosol-generating article 2.

According to one embodiment, the cartridge 19 may be removably coupled to the housing 10. For example, a space may be formed in one side of the housing 10, and at least a portion of the cartridge 19 may be inserted into the space formed in one side of the housing 10 so that the cartridge 19 is mounted to the housing 10. Alternatively, the cartridge 19 may be integrally formed with the housing 10.

According to one embodiment, the aerosol-generating device 1 and/or the cartridge 19 may be provided with an airflow channel through which air flows. For example, the housing 10 may include a structure allowing outside air to be introduced into the housing 10 in the state in which the cartridge 19 is inserted thereinto. The introduced air may pass through the cartridge 19, may be introduced into the insertion space through the airflow channel CN, and then may flow to the user's oral cavity. The airflow channel CN may include various structures for reducing residual droplets or making the flow of air smooth.

Although it is illustrated in FIG. 3 that the cartridge 19 is located beside the aerosol-generating article 2 and the airflow channel CN is formed from the side surface of the aerosol-generating article 2 to the lower end (i.e., upstream side) of the aerosol-generating article 2, the positions of the cartridge 19 and the airflow channel CN are not limited thereto. For example, the cartridge 19 may be located adjacent to the lower end (i.e., upstream side) of the aerosol-generating article 2. In this case, the airflow channel CN may be formed in a substantially straight shape to connect the cartridge 19 to the lower end (i.e., upstream side) of the aerosol-generating article 2.

According to one embodiment, the cartridge 19 may include a storage part C0 that contains an aerosol-generating substance, a cartridge heater 24, and/or a liquid delivery part that is impregnated with (contains) the aerosol-generating substance. The liquid delivery part may be impregnated with the aerosol-generating substance supplied from the chamber C0. For example, the liquid delivery part may include a wick formed of, e.g., cotton fiber, ceramic fiber, glass fiber, or porous ceramic.

According to one embodiment, the cartridge heater 24 may heat the aerosol-generating substance contained in the cartridge 19. For example, the cartridge heater 24 may include an electro-resistive heater and/or an induction heater.

In an example, the electro-resistive heater may include an electro-resistive material, and may generate heat as current flows through the electro-resistive material. In another example, in the case of an induction heater, the aerosol-generating device 1 may further include an induction coil (not shown) provided around the induction heater. The induction heater may include a susceptor, and may generate heat based on a magnetic field generated by the induction coil (not shown). The cartridge heater 24 may be formed in a coil shape surrounding (or wound around) the liquid delivery part and/or in a shape (e.g., a patterned shape) contacting one side of the liquid delivery part.

Unlike the configuration shown in the drawings, the cartridge heater 24 may be included in the aerosol-generating device 1. For example, the cartridge heater 24 may be included inside the housing 10. In this case, the cartridge 19 and the cartridge heater 24 may be separated by removal of the cartridge 19.

According to one embodiment, an aerosol may be generated based on generation of heat by the cartridge heater 24. For example, as the aerosol-generating substance impregnated in the liquid delivery part is heated by the cartridge heater 24, vapor may be generated from the aerosol-generating substance, and an aerosol may be generated as the generated vapor is mixed with the outside air introduced into the cartridge 19. The aerosol generated by the cartridge heater 24 may be introduced into the aerosol-generating article 2 through the airflow channel CN. While the aerosol passes through the aerosol-generating article 2, tobacco or a flavoring substance may be added to the aerosol, and the aerosol containing the tobacco or the flavoring substance may be inhaled into the user's oral cavity through one end of the aerosol-generating article 2.

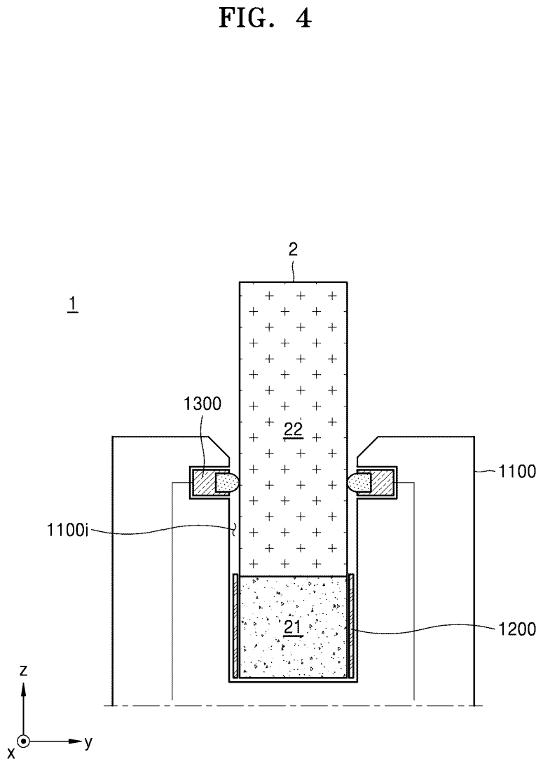

FIG. 4 is a cross-sectional view of an aerosol generating device 1 according to an embodiment.

Referring to FIG. 4, the aerosol generating device 1 according to an embodiment may include a housing 1100, a heater 1200, and a support portion 1300.

The housing 1100 may correspond to the same component as the housing (e.g., the housing 10 of FIG. 2A) described above. The housing 1100 may form the overall exterior of the aerosol generating device 1, and include an inner space in which components of the aerosol generating device 1 may be disposed.

While only an embodiment in which the housing 1100 is formed entirely as a square pillar in cross-section is illustrated, the shape of the housing 1100 is not limited thereto, and the housing 1100 may have an overall cylindrical shape or polygonal pillar shape.

The housing 1100 may include an opening into which an aerosol generating article 2 may be inserted into the housing 1100. At least a part of the aerosol generating article 2 may be inserted into or accommodated in the housing 1100 through the opening.

The housing 1100 may include an insertion space 1100i accommodating the aerosol generating article 2 therein. The insertion space 1100i may be formed in an upper portion of the housing 1100. The insertion space 1100i may be opened upward to be connected to the opening.

The insertion space 1100i may have a cylindrical shape extending vertically. At least a part of the aerosol generating article 2 may be accommodated in the housing 1100 through an opening in an upper side of the insertion space 1100i. In this regard, a depth of the insertion space 1100i may correspond to a length of a region including an aerosol generating material or a medium in the aerosol generating article 2.

The heater 1200 may have the same component as the heater (e.g., the heater 18 of FIG. 1) described above. The heater 1200 may generate an aerosol from the aerosol generating article 2 by heating the aerosol generating article 2 accommodated in the insertion space 1100i. The heater 1200 may extend vertically along the insertion space 1100i.

According to an embodiment, the heater 1200 may have a cylindrical shape surrounding at least a part of the aerosol generating article 2. In this case, the heater 1200 may heat an outer circumferential surface of the aerosol generating rod 2100 as a cylindrical electric resistive heater. The heater 1200 disposed outside the aerosol generating article 2 may be referred to as an ‘external heating type heater’.

However, the embodiment is not limited to the shape and arrangement of the illustrated heater 1200. As another example, the heater 1200 may include a cylindrical susceptor surrounding at least a part of the insertion space 1100i and an induction coil surrounding the susceptor.

In addition, the heater 1200 is not limited to the external heating type heater 1200. As another example, the heater 1200 may be inserted into the aerosol generating article 2 accommodated in the insertion space 1100i to heat the inside of the aerosol generating article 2.

At least one region of the aerosol generating article 2 accommodated in the insertion space 1100i may be heated by the heater 1200, and vaporized particles generated by heating the aerosol generating article 2 and air flowing into the inner space of the housing 1100 through an air inlet (e.g., an opening) formed in one region of the housing 1100 may be mixed to generate an aerosol.

In this regard, the aerosol generating article 2 inserted into the insertion space 1100i may be similar to a general combustion type cigarette. For example, the aerosol generating article 2 may be divided into an aerosol generating rod 21 including an aerosol generating material and a filter rod 22 including a filter.

The aerosol generating rod 21 may be formed of sheets, strands, and tiny bits cut from a tobacco sheet. In addition, the aerosol generating rod 21 may be surrounded by a heat conductive material. For example, the heat conductive material may be a metal foil such as aluminum foil, but is not limited thereto.

The filter rod 22 may be a cellulose acetate filter. The filter load 22 may include at least one segment. For example, the filter rod 22 may include a first segment that cools an aerosol and a second segment that filters a certain component included in the aerosol.

According to the embodiment, an aerosol generating material may also be included in the filter rod 22 of the aerosol generating article 2. For example, an aerosol generating material made in the form of granules or capsules may be inserted into the filter rod 22.

As shown, a part of each of the aerosol generating rod 21 and the filter rod 22 may be inserted into the insertion space 1100i. The other part of the filter rod 22 may be exposed to the outside of the aerosol generating device 1. In this regard, the aerosol generating rod 21 may be surrounded by the external heating type heater 1200.

The user may inhale the aerosol by holding the other end of the filter rod 22 by the user's mouth. In this regard, the aerosol may be generated by allowing outside air to pass through the aerosol generating rod 21 along with heating by the heater 1200, and the generated aerosol may pass through the filter rod 22 and be delivered to the user's mouth.

Meanwhile, the heater 1200 may be a cartridge heater (e.g., the cartridge heater 19 of FIG. 3). In this case, the aerosol generating article 2 may be the cartridge 19 of FIG. 3 rather than a cigarette.

The support portion 1300 is a component for supporting the aerosol generating article 2 accommodated in the insertion space 1100i. In this regard, the support portion 1300 may be disposed in an upper portion of the heater 1200. That is, the support portion 1300 and the heater 1200 may be sequentially disposed in a direction in which the aerosol generating article 2 is inserted (e.g., −z direction). Accordingly, the aerosol generating article 2 may first contact the support portion 1300, and then be further inserted in an insertion direction to face the heater 1200 while being inserted into the insertion space 1100i.

According to an embodiment, at least a part of the support portion 1300 may move in a first direction (e.g., +y direction) facing the insertion space 1100i or in a second direction (e.g., −y direction) away from the insertion space 1100i. In this regard, the first direction and the second direction may be directions crossing a longitudinal direction of the insertion space 1100i (e.g., the y-axis direction), and opposite to each other.

Accordingly, at least a part of the support portion 1300 may move to support the aerosol generating article 2 having a dimension corresponding to a dimension of the inserted aerosol generating article 2. Even when there is a deviation in the dimension for each aerosol generating article 2, the support portion 1300 may support the aerosol generating article 2 inserted into the insertion space 1100i regardless of the deviation.

Even when the aerosol generating article 2 is manufactured to be larger or smaller than a predetermined design dimension during the manufacturing process, and the diameter of the aerosol generating article 2 is different from the predetermined design dimension, the aerosol generating device 1 may firmly support the inserted aerosol generating article 2 regardless of such a difference. Therefore, problems that may be caused by the dimensional deviation of the aerosol generating article 2 may be prevented.

According to an embodiment, the support portion 1300 may include a material that conducts electricity. Accordingly, when power is supplied to the support portion 1300 having electrical conductivity, current may flow. However, a value of current flowing through the support portion 1300 may change in response to a change in the state of the insertion space 1100i.

In this regard, ‘a case where the value of current changes’ may include a case where the current value becomes 0 because no current flows through the support portion 1300. For example, when the support portion 1300 is in an electrically open state, even when voltage is applied to the support portion 1300, no current may flow through the support portion 1300.

Hereinafter, an example of the support portion 1300 through which current may flow while at least a part thereof may move and a peripheral structure thereof will be described.

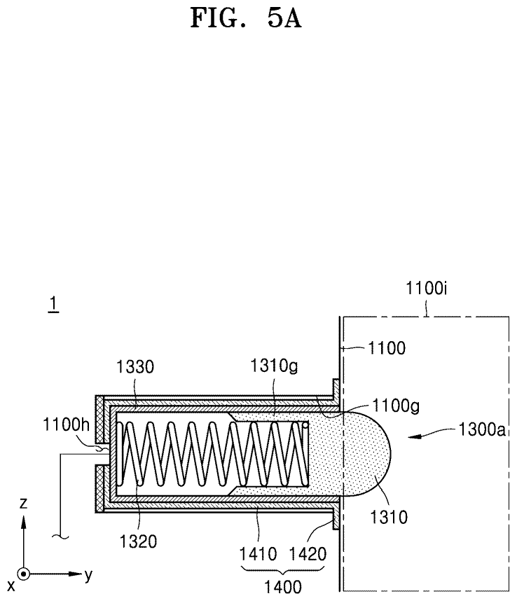

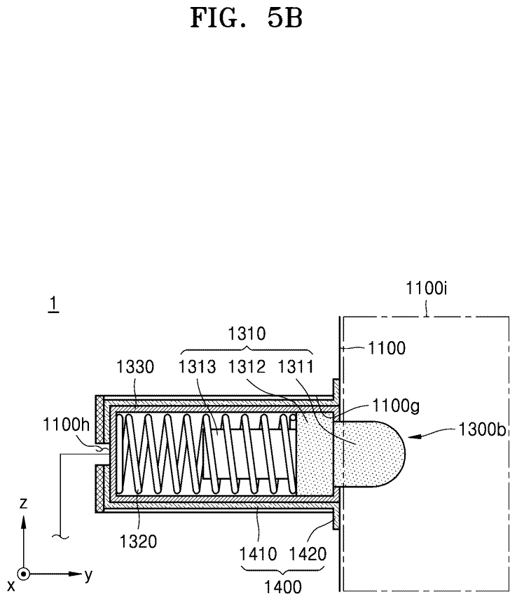

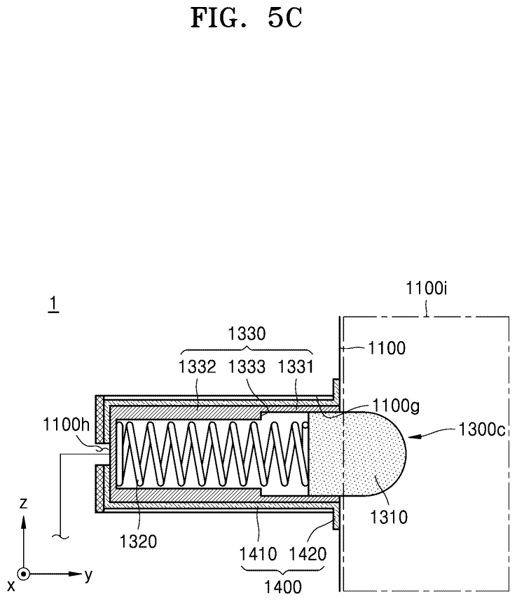

FIGS. 5A to 5C are cross-sectional views illustrating examples of support portions 1300a, 1300b, and 1300c applied to the aerosol generating device 1 according to embodiments.

Referring to FIGS. 5A to 5C, the aerosol generating device 1 according to embodiments may include the housing 1100 and the support portions 1300a, 1300b, and 1300c. Detailed descriptions of the configuration and effects of the aerosol generating device 1 which are redundant with those described with reference to FIG. 4 will be omitted.

Before describing individual characteristics of each of the support portions 1300a, 1300b, and 1300c shown in FIGS. 5A to 5C, common characteristics of the aerosol generating device 1 shown in FIGS. 5A to 5C will be described. In this regard, the common description of the support portions 1300a, 1300b, and 1300c may also be applied to the support portion 1300 of FIG. 4.

The housing 1100 may include a groove 1100g that extends in a direction crossing a longitudinal direction (e.g., z-axis direction) of the housing 1100 and is opened toward the insertion space 1100i. In this regard, the support portions 1300a, 1300b, and 1300c may be inserted into the groove 1100g and coupled to the housing 1100.

The housing 1100 may include a hole 1100h disposed in the bottom of the groove 1100g facing the insertion space 1100i. The support portions 1300a, 1300b, and 1300c mounted on the groove 1100g may be connected to wires passing through the hole 1100h. The support portions 1300a, 1300b, and 1300c may be connected to other components through the wires. Power may be supplied to the support portions 1300a, 1300b, and 1300c along the wires to allow current to flow therethrough.

According to embodiments, each of the support portions 1300a, 1300b, and 1300c shown in FIGS. 5A to 5C may commonly include a contact member 1310, an elastic member 1320, and a guide member 1330.

The contact member 1310 is a component supporting an outer circumferential surface of the aerosol generating article 2 accommodated in the insertion space 1100i. A part of the contact member 1310 may protrude to the insertion space 1100i, and the other part of the contact member 1310 may be located inside the groove 1100g.

At least a part of the contact member 1310 protruding to the insertion space 1100i may be exposed to the insertion space 1100i and contact the aerosol generating article 2 accommodated in the insertion space 1100i.

In a process of inserting the aerosol generating article 2 into the insertion space 1100i, one end of the aerosol generating article 2 may first contact the contact member 1310. Thereafter, when the insertion of the aerosol generating article 2 continues, the aerosol generating article 2 may press the contact member 1310 toward the bottom of the insertion space 1100i.

In this regard, by the shape of the contact member 1310, the contact member 1310 may move in a second direction (e.g., −y direction) away from the insertion space 1100i. As the contact member 1310 moves in the second direction, a contact portion between the aerosol generating article 2 and the contact member 1310 may change. When the contact member 1310 no longer moves in the second direction, the contact member 1310 may contact the outer circumferential surface of the aerosol generating article 2.

The elastic member 1320 is a component connected to the contact member 1310 and pressing the contact member 1310 through an elastic restoring force. The elastic member 1320 may be disposed inside the groove 1100g. When the contact member 1310 moves in the second direction due to the insertion of the aerosol generating article 2, the elastic member 1320 may be compressed in the second direction.

As the elastic member 1320 is compressed in the second direction, the elastic member 1320 may apply an elastic force in the first direction (e.g., +y direction). In this regard, because an end of the elastic member 1320 in the first direction is connected to the contact member 1310, the elastic member 1320 may press the contact member 1310 in the first direction. Accordingly, the contact member 1310 may support the outer circumferential surface of the aerosol generating article 2.

The guide member 1330 is a component accommodating at least a part of the contact member 1310 and the elastic member 1320, and guiding the movement of the contact member 1310. The guide member 1330 may have a cup shape extending in one direction (e.g., y-axis direction).

At least a part of the contact member 1310 and the elastic member 1320 may be disposed inside the guide member 1330 in the cup shape. In this regard, one end of the elastic member 1320 may be connected to the contact member 1310, and the other end of the elastic member 1320 may be connected to a bottom surface of the guide member 1330.

The contact member 1310 may move in a direction in which the guide member 1330 extends. Because the guide member 1330 extends only in one direction and surrounds the contact member 1310, the contact member 1310 may move only in one direction.

Similarly, because the elastic member 1320 connected to the contact member 1310 is also surrounded by the guide member 1330, the elastic member 1320 may be compressed or elongated only in one direction.

As shown, the guide member 1330 may be connected to the wires passing through the hole 1100h. In this regard, because the contact member 1310, the elastic member 1320, and the guide member 1330 all have electrical conductivity, when power is supplied thereto through the wires, the contact member (1310, the elastic member 1320, and the guide member 1330 may be electrically connected to each other.

In this regard, when current flows through the guide member 1330 which occupies a large part of the exterior of each of the support portions 1300a, 1300b, and 1300c, current may also flow through one region of the housing 1100 in contact with an outer surface of the guide member 1330. When current flows through one region of the housing 1100g surrounding the groove 1100g, current may flow through a region not desired by the user, which may cause a failure.

To solve this problem, the aerosol generating device 1 according to an embodiment may further include a shielding portion 1400. The shielding portion 1400 may be mounted on the groove 1100g and accommodate at least a part of each of the support portions 1300a, 1300b, and 1300c to surround the guide member 1330.

According to this arrangement, an outer surface of the shielding portion 1400 may be in contact with one region of the housing 1100 forming the circumference of the groove 1100g, and an inner surface of the shielding portion 1400 may be in contact with the guide member 1330 of each of the support portions 1300a, 1300b, and 1300c.

That is, the support portions 1300a, 1300b, and 1300c, the shielding portion 1400, and one region of the housing 1100 may be sequentially disposed from a center axis in a direction in which the groove 1100g extends toward the circumference of the groove 1100g.

According to an embodiment, a hole (not shown) may be formed in the bottom of the shielding portion 1400 facing the insertion space 1100i. The hole formed in the bottom of the shielding portion 1400 may be aligned with the hole 1100h formed in the housing 1100. Accordingly, the wires passing through the hole 1100h may pass through the hole of the shielding portion 1400 to be connected to the guide member 1330.

The shielding portion 1400 may include a material that does not conduct electricity. Accordingly, the shielding portion 1400 may block current from flowing from the guide member 1330 or the support portion 1300a, 1300b, and 1300c to one region of the housing 1100. Due to the arrangement of the shielding portion 1400, a phenomenon in which current leaks through one region of the housing 1100 may be prevented.

According to the embodiment, the shielding portion 1400 may serve as an extractor that facilitates separation of the support portions 1300a, 1300b, and 1300c from the groove 1100g. In general, the support portions 1300a, 1300b, and 1300c mounted on the groove 1100g need to be firmly supported so as not to move inside the groove 1100g. However, in some cases, when the support portions 1300a, 1300b, and 1300c need to be redisposed, the support portions 1300a, 1300b, and 1300c need to be separated from the groove 1100g by user manipulation.

As shown, the shielding portion 1400 may include a body part 1410 extending in the longitudinal direction of the support portions 1300a, 1300b, and 1300c and surrounding the support portions 1300a, 1300b, and 1300c, and a head part 1420 protruding from the body part 1410 to the outside of the body part 1410.

The shape of the groove 1100g in which the shielding portion 1400 is mounted may also change in response to the shape of the shielding portion 1400. As shown, the groove 1100g may include a first region having a first diameter sequentially along the first direction (e.g., +y direction) and a second region having a second diameter greater than the first diameter.

When the shielding portion 1400 is mounted on the groove 1100g, the body part 1410 of the shielding portion 1400 may be located in the first region, and the head part 1420 of the shielding portion 1400 may be located in the second region.

Like the support portions 1300a, 1300b, and 1300c being in a straight shape extending in one direction, when the shape of the shielding portion 1400 is also in the straight shape of only the body part 1410, the shielding portion 1400 mounted on the groove 1100g may be difficult to separate from the groove 1100g.

In this regard, a length of the head part 1420 (meaning a thickness of the head part 1420) extending in a longitudinal direction of the shielding portion 1400 may be a length that makes it easy for the user to separate the head part 1420 from the second region of the groove 1100g by using a tool such as tweezers.

In conclusion, the shielding portion 1400 may include a structure that is easily separated from the groove 1100g by the user manipulation, and accordingly, the support portions 1300a, 1300b, and 1300c accommodated in the shielding portion 1400 may be easily separated from the groove 1100g by the user manipulation.

Meanwhile, according to an embodiment, the guide member 1330 of each of the support portions 1300a, 1300b, and 1300c may include a material having no electrical conductivity. In this case, a hole (not shown) may be formed in the bottom of the guide member 1330. The hole formed in the guide member 1330 may be aligned with the hole 1100h formed in the housing 1100. Therefore, the wires passing through the hole 1100h may pass through the hole of the guide member 1330 to be connected to the elastic member 1320.

Because the guide member 1330 does not have electrical conductivity, the guide member 1330 may serve as the shielding portion 1400 described above. In this regard, the shielding portion 1400 may not be disposed inside the aerosol generating device 1.

In addition, according to the embodiment, the guide member 1330 may not be disposed. In this case, the movement of the contact member 1310 and the deformation of the elastic member 1320 may be guided by one region of the housing 1100 surrounding the groove 1100g and extending in the longitudinal direction of the groove 1100g. In this case, an insulating tape may be attached to one region of the housing 1100.

Referring to FIG. 5A, the contact member 1310 of the first support portion 1300a may accommodate a part of the elastic member 1320. One part 1310g of the contact member 1310 in which the elastic member 1320 is accommodated may have a cylindrical shape. An outer circumferential surface of the corresponding portion 1310g having the cylindrical shape may be disposed adjacent to the guide member 1330, and an inner circumferential surface of the corresponding portion 1310g may be disposed adjacent to the elastic member 1320.

Accordingly, the movement of the contact member 1310 may be guided by the guide member 1330 in one direction, and the compression or elongation of the elastic member 1320 may be guided by the contact member 1310 in one direction.

Referring to FIG. 5B, the contact member 1310 of the support portion 1300b may include a first part 1311 that is in contact with the aerosol generating article 2 and may be exposed to the insertion space 1100i, a second part 1312 having a circular shape and an outer surface adjacent to the inner surface of the guide member 1330, and a third part 1313 having a circular shape and inserted into an inner space of the elastic member 1320 in a spring shape. In this regard, a diameter of the second part 1312 may be greater than a diameter of the third part 1313.

One end of the first part 1311 may be in contact with the aerosol generating article 2, and the other end of the first part 1311 may be connected to one end of the second part 1312. One end of the second part 1312 may be blocked by a part of the guide member 1330 protruding inward to surround the first part 1311. Accordingly, the movement of the contact member 1310 in the first direction may be restricted.

Accordingly, even though the contact member 1310 protrudes excessively into the insertion space 1100i and the aerosol generating article 2 contacts the contact member 1310, a phenomenon in which the contact member 1310 is not pushed in the second direction may be prevented.

The other end of the second part 1312 may be connected to one end of the third part 1313. The other end of the third part 1313 may be located in the inner space of the elastic member 1320. In this regard, the elastic member 1320 disposed to surround the third part 1313 may be connected to the other end of the second part 1312 through one end thereof. One end of the elastic member 1320 may be disposed around one end of the third part 1313. Due to the structure, the elastic member 1320 may be coupled to the contact member 1310.

On the other hand, because the second part 1312 of the contact member 1310 and the elastic member 1320 are disposed adjacent to an inner surface of the guide member 1330, the movement of the contact member 1310 and the deformation of the elastic member 1320 may be guided by the guide member 1330 in one direction.

Referring to FIG. 5C, the guide member 1330 may include a first region 1331 surrounding the contact member 1310 and a second region 1332 surrounding the elastic member 1320. In this regard, an inner diameter of the first region 1331 may be greater than an inner diameter of the second region 1332. A step 1333 may exist at an area where the first region 1331 and the second region 1332 are connected to each other.

A diameter of the contact member 1310 disposed in the first region 1331 may be greater than a diameter of the elastic member 1320 in the spring shape disposed over in the first region 1331 and the second region 1332. Accordingly, when the contact member 1310 moves in the second direction by the insertion of the aerosol generating article 2, the contact member 1310 may be blocked by the step 1333. Accordingly, movement of the contact member 1310 in the second direction may be restricted.

Accordingly, a phenomenon in which the contact member 1310 is completely inserted into the groove 1100g and does not protrude to the insertion space 1100i may be prevented. As at least a part of the contact member 1310 always protrudes to the insertion space 1100i, an empty space may always be secured between an inner wall of the housing 1100 forming the insertion space 1100i and the aerosol generating article 2 accommodated in the insertion space 1100i. When the empty space is used as an airflow passage, an airflow passage may always be secured even though the aerosol generating article 2 of any dimension is inserted.

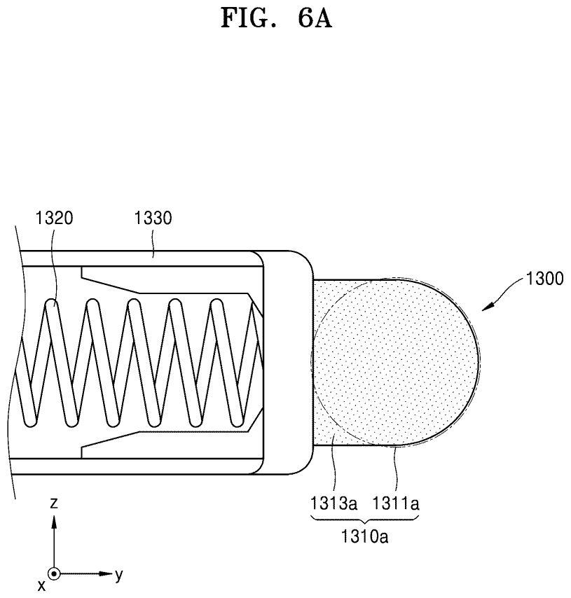

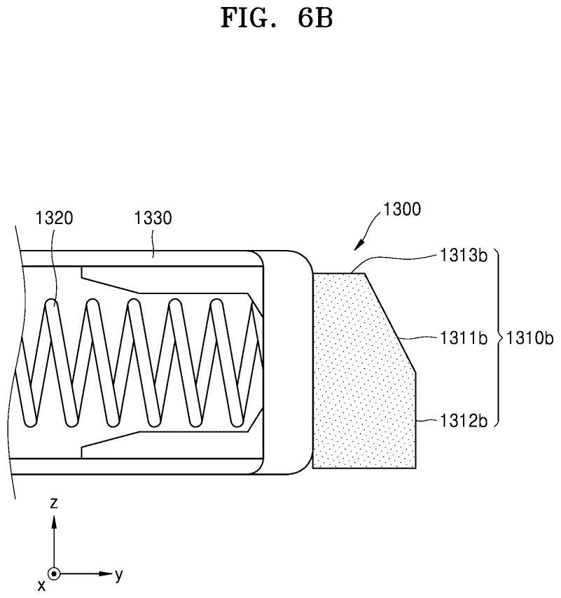

FIGS. 6A and 6B are respectively cross-sectional views illustrating examples of contact members 1310a and 1310b of the support portion 1300 in contact with the aerosol generating article 2.

Referring to FIGS. 6A and 6B, the aerosol generating device 1 according to embodiments may include the housing 1100 and the support portion 1300. Detailed descriptions of the configuration and effects of the aerosol generating device 1 which are redundant with those described above will be omitted.

The support portions 1300 shown in FIGS. 6A and 6B may respectively include the contact members 1310a and 1310b in different shapes. When the aerosol generating article 2 is inserted into the insertion space 1100i, shapes of the contact members 1310a and 1310b may affect the insertion and support of the aerosol generating article 2.

Referring to FIG. 6A, the contact member 1310a may include a contact part 1311a including a curved surface in contact with the aerosol generating article 2, and a non-contact part 1313a extending from the contact part 1311a in a second direction (e.g., −y direction).

Because the contact part 1311a includes the curved surface, when the aerosol generating article 2 is inserted, the contact part 1311a may be in point contact with one end of the aerosol generating article 2.

As the aerosol generating article 2 is further inserted, a part where the contact part 1311a is in contact with the aerosol generating article 2 may change. Specifically, a contact area of the contact part 1311a may gradually move downward. Simultaneously, the contact member 1310a may move in the second direction.

When the aerosol generating article 2 is in contact with a part of the contact part 1311a maximally protruding to the insertion space 1100i, the contact member 1310a may no longer move in the second direction, and the contact part 1311a may be in contact with an outer circumferential surface of the aerosol generating article 2. In this regard, because the elastic member 1320 compressed in the second direction presses the contact member 1310a in a first direction, the aerosol generating article 2 may be firmly supported by the contact part 1311a.

The non-contact part 1313a may have a cylindrical shape extending in the second direction. The non-contact part 1313a may serve as a guide such that the contact member 1310a may move only in one direction (e.g., the first direction and the second direction) in which the groove 1100g extends.

Considering the shape of the non-contact part 1313a, when the aerosol generating article 2 contacts the non-contact part 1313a, the contact member 1310a may not move in the second direction. Therefore, the non-contact part 1313a may protrude to the insertion space 1100i only so as not to be in contact with the inserted aerosol generating article 2.

On the other hand, as the contact member 1310a in in point contact with the aerosol generating article 2, the contact area between the contact member 1310a and the aerosol generating article 2 is relatively small. However, because the contact member 1310a includes the curved surface, when the contact member 1310a strongly presses an outer circumferential surface of the aerosol generating article 2 according to a degree to which the elastic member 1320 presses, the contact member 1310a and the aerosol generating article 2 may be in surface contact with each other. Therefore, because the area where the contact member 1310a and the outer circumferential surface of the aerosol generating article 2 are in contact with each other relatively increases, the aerosol generating article 2 may be firmly supported.

Referring to FIG. 6B, the contact member 1310b may include a first contact part 1311b in contact with the aerosol generating article 2 during an insertion process of the aerosol generating article 2, a second contact part 1312b in contact with the aerosol generating article 2 while the insertion is completed, and a non-contact part 1313b extending from one end of the first contact part 1311b in the second direction (e.g., −y direction).

One end of the first contact part 1311b may be connected to the non-contact part 1313b, and the other end of the first contact part 1311b may be connected to the second contact part 1312b. Therefore, the non-contact part 1313b and the second contact part 1312b may be connected to each other by the first contact part 1311b.

The first contact part 1311b may include an inclined surface which is inclined with respect to a longitudinal direction of the insertion space 1100i. Due to the inclined surface, the first contact part 1311b may further protrude to the insertion space 1100i downward.

On the other hand, due to the inclined surface, when the aerosol generating article 2 is inserted, the contact part 1311a may be in line contact with one end of the aerosol generating article 2. As the aerosol generating article 2 is further inserted, an area where the first contact part 1311b is in contact with the aerosol generating article 2 may change. Specifically, the contact area of the first contact part 1311b may gradually move downward. Simultaneously, the contact member 1310b may move in the second direction.

The second contact part 1312b may extend in a circumferential direction and longitudinal direction of the insertion space 1100i. For example, the second contact part 1312b may have a curved shape surrounding at least a part of the insertion space 1100i. The second contact part 1312b may be disposed to face the aerosol generating article 2 accommodated in the insertion space 1100i.

When the aerosol generating article 2 contacts the second contact part 1312b, the contact member 1310b may no longer move in the second direction, and the second contact part 1312b may contact the outer circumferential surface of the aerosol generating article 2. In this regard, because the elastic member 1320 compressed in the second direction presses the contact member 1310b in the first direction, the aerosol generating article 2 may be firmly supported by the second contact portion 1312b.

According to the embodiment shown in FIG. 6B, the aerosol generating article 2 may be in line contact with the first contact part 1311b while being inserted. The contact area between the first contact part 1311b and the aerosol generating article 2 is relatively large compared to the point contact. Accordingly, the force required to apply pressure to the contact member 1310b enough to move in the second direction while the aerosol generating article 2 is inserted may be relatively small compared to the point contact. As a result, the excessive force may be applied during the insertion process, and thus damage such as crushing one end of the aerosol generating article 2 by the first contact part 1311b may be prevented.

In addition, even after the insertion of the aerosol generating article 2 is completed, the aerosol generating article 2 may be in line or surface contact with the second contact part 1312b, and thus the aerosol generating article 2 may be firmly supported by the support portion 1300.

Hereinafter, a change in an operation state of the support portion 1300 while the aerosol generating article 2 is inserted into the insertion space 1100i will be described.

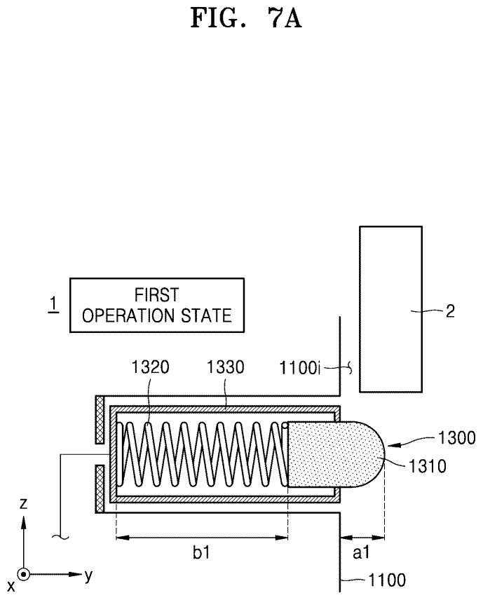

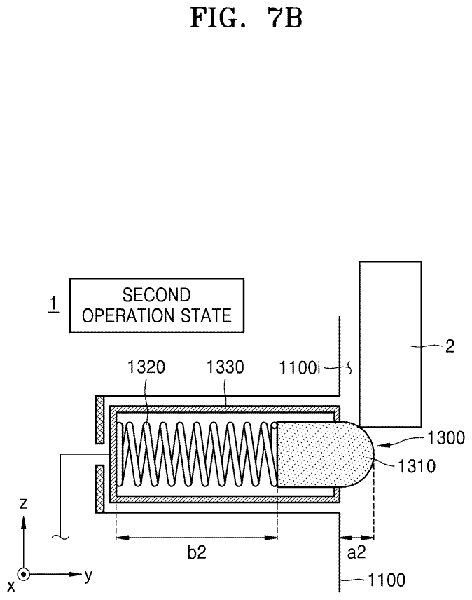

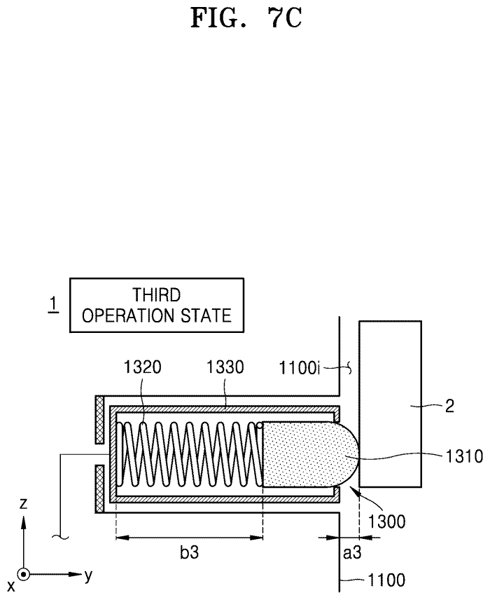

FIGS. 7A to 7C are cross-sectional views illustrating operation states of the support portion 1300 applied to the aerosol generating device 1 according to an embodiment.

Referring to FIGS. 7A to 7C, the aerosol generating device 1 according to embodiments may include the housing 1100 and the support portion 1300. Detailed descriptions of the configuration and effects of the aerosol generating device 1 which are redundant with those described above will be omitted.

Referring to FIG. 7A, a first operation state just before the aerosol generating article 2 inserted into the insertion space 1100i is in contact with the support portion 1300 is illustrated. In this regard, because the support portion 1300 is not in contact with the aerosol generating article 2, the support portion 1300 is not pressed by the aerosol generating article 2.

With regard to describing the operation of the support portion 1300, the first operation state may be the same as a state where the aerosol generating article 2 is not inserted into the insertion space 1100i. That is, the first operation state may mean a non-use state of the aerosol generating device 1.

In the first operation state, the contact member 1310 may be maximally drawn toward the insertion space 1100i. For example, the contact member 1310 may protrude from an inner wall of the housing 1100 surrounding the insertion space 1100i by a first distance a1. In addition, in the first operation state, the elastic member 1320 may remain undeformed. Therefore, a length of the elastic member 1320 may maintain a first length b1.

Referring to FIG. 7B, a second operation state where one end of the aerosol generating article 2 is in contact with the support portion 1300 and continues to be inserted into the insertion space 1100i is illustrated. In this regard, the support portion 1300 may be pressed by one end of the aerosol generating article 2 to move in a second direction (e.g., −y direction).

In the second operation state, a part of the contact member 1310 exposed to the insertion space 1100i may be inserted into the groove 1100g. Accordingly, the contact member 1310 may protrude from the inner wall of the housing 1100 surrounding the insertion space 1100i by a second distance a2 less than the first distance a1. In addition, in the second operation state, the elastic member 1320 may be compressed, so that the length of the elastic member 1320 may a second length b2 less than the first length b1.

Referring to FIG. 7C, a third operation state where an outer circumferential surface of the aerosol generating article 2 contacts the support portion 1300 and continues to be inserted into the insertion space 1100i is illustrated. In this regard, the support portion 1300 may no longer move in the second direction (e.g., −y direction).

With regard to describing the operation of the support portion 1300, the third operation state may be the same as a state where the aerosol generating article 2 is completely inserted into the insertion space 1100i.

In the third operation state, the contact member 1310 may be maximally inserted into the groove 1100g. For example, the contact member 1310 may protrude from the inner wall of the housing 1100 surrounding the insertion space 1100i by a third distance a3 less than the second distance a2. In addition, in the third operation state, the elastic member 1320 is maximally compressed, so that the length of the elastic member 1320 may be a third length b3 less than the second length b2.

On the other hand, the expressions “the contact member 1310 has been maximally inserted” and “the elastic member 1320 has been maximally compressed” are used to explain the operation state of the support portion 1300 with respect to the insertion of one aerosol generating article 2 with a specific dimension (e.g., diameter). According to the dimension of the aerosol generating article 2, the maximum degree of insertion of the contact member 1310 and the maximum degree of compression of the elastic member 1320 may change.

That is, in the third operation state, a length a3 of the contact member 1310 protruding the insertion space 1100i and a length b3 of the compressed elastic member 1320 may change according to the dimension of the aerosol generating article 2 inserted into the insertion space 1100i.

Hereinafter, a case where current flows through the support portion 1300 through the aerosol generating article 2 will be described.

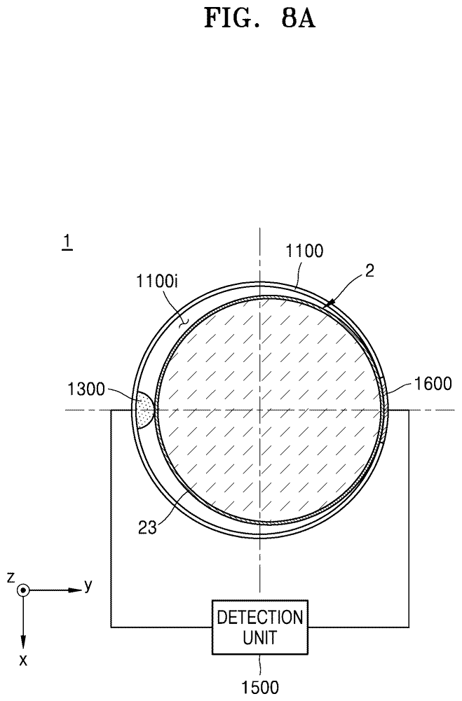

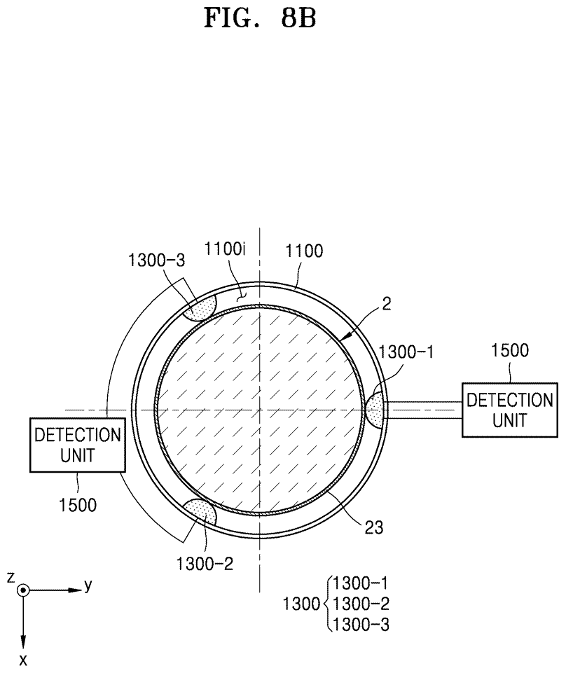

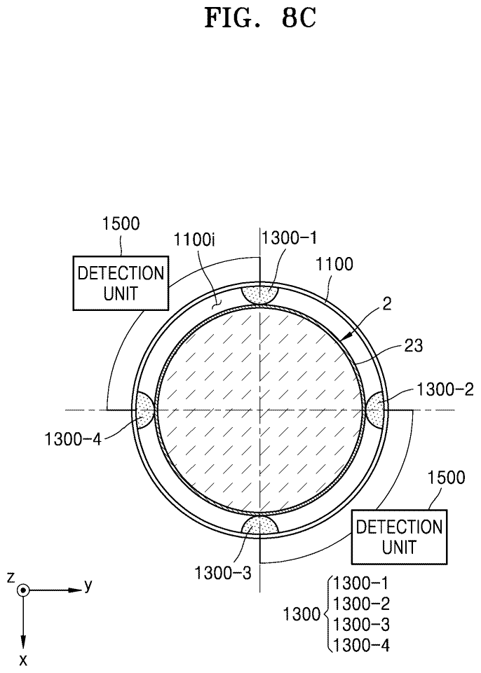

FIGS. 8A to 8C are cross-sectional views illustrating various numbers of support portions 1300 disposed in the aerosol generating device 1 in a circumferential direction of the insertion space 1100i according to the embodiments.

Referring to FIGS. 8A to 8C, the aerosol generating device 1 according to embodiments may include the housing 1100, the support portion 1300, and a detection unit 1500. Detailed descriptions of the configuration and effects of the aerosol generating device 1 which are redundant with those described above will be omitted.

In FIGS. 8A to 8C, different numbers of support portions 1300 are disposed. Each of the support portions 1300 may be connected to the detection unit 1500. The detection unit 1500 is a component connected to the support portion 1300 to detect a change in a state of the support portion 1300. For example, the detection unit 1500 may detect a change in current value flowing through the support portion 1300. The detection unit 1500 may correspond to the same component as the sensor unit (e.g., the sensor unit 13 of FIG. 1) described above.

A control unit (e.g., the control unit 12 of FIG. 1) may be electrically connected to the detection unit 1500 to be a subject of determining the detection of the detection unit 1500. The control unit may determine a sensing target of the detection unit 1500 (e.g., the change in the state of the support portion 1300) through the detection unit 1500.

For example, when the detection unit 1500 generates a signal in response to the change in the state of the support portion 1300, the control unit may determine the state of the support portion 1300 and/or the change in the state of the support portion 1300 based on the signal generated by the detection unit 1500.

According to the embodiment, the detection unit 1500 may be omitted. That is, the separate detection unit 1500 may not be disposed inside the aerosol generating device 1. In this regard, the control unit may be directly connected to the support portion 1300 to detect the change in the state of the support portion 1300. For example, the control unit may detect the change in the current value flowing through the support portion 1300 and determine the state of the support portion 1300 and/or the change in the state of the support portion 1300.

On the other hand, when multiple detection units 1500 are illustrated in the drawing, a plurality of detection units 1500 may actually be disposed inside the aerosol generating device 1, but only one detection unit 1500 may be disposed according to the embodiment. In this case, regardless of the plurality of detection units 1500 being illustrated, all the plurality of detection units 1500 correspond to one detection unit 1500, and each of the support portions 1300 may be connected to one detection unit 1500.

In addition, when the plurality of detection units 1500 are disposed, at least some of the plurality of detection units 1500 may perform the same function, and all the plurality of detection units 1500 may perform different functions.

Hereinafter, it is assumed that each of the detection units 1500 illustrated in the drawing constitutes a closed circuit separate from the support portions 1300 or terminals 1600 connected to both ends of the detection unit 1500, and that the separate closed circuits do not electrically affect each other. The description of the detection unit 1500 may be equally applied to the following drawings unless otherwise stated.

When the aerosol generating article 2 is inserted into the insertion space 1100i, because the insertion space 1100i which was an empty space is filled with the aerosol generating article 2, a state of the insertion space 1100i may be considered to have changed. That is, the insertion of the aerosol generating article 2 into the insertion space 1100i may be an example where the state of the insertion space 1100i changes.

When the aerosol generating article 2 is accommodated in the insertion space 1100i, the support portion 1300 may contact an identifier 23 included in the aerosol generating article 2. The identifier 23 may include a band shape surrounding an outer circumferential surface of the aerosol generating article 2 in a circumferential direction of the aerosol generating article 2.

The identifier 23 may include a material that conducts electricity such as metal. That is, because the identifier 23 has electrical conductivity, when the support portion 1300 and the identifier 23 contact each other, current may flow along the identifier 23 of the aerosol generating article 2. Accordingly, a value of the current flowing through the support portion 1300 may change.

In order to contact the support portion 1300 and the identifier 23 to each other, because the aerosol generating article 2 needs to be inserted into the insertion space 1100i, it may be seen that the value of current flowing through the support portion 1300 changes in response to the change in the state of the insertion space 1100i. Hereinafter, an example in which current flows through the support portion 1300 and the aerosol generating article 2 will be described.

Referring to FIG. 8A, one support portion 1300 is disposed inside the aerosol generating device 1. Even in this case, the support portion 1300 may support the aerosol generating article 2 with various dimensions.

In this regard, the aerosol generating device 1 may include the terminal 1600 facing the support portion 1300. At least a part of the terminal 1600 may be disposed to be exposed to the insertion space 1100i.

The support portion 1300 and the terminal 1600 may be connected to both ends of the detection unit 1500, respectively. However, because the support portion 1300 and the terminal 1600 are spaced apart from each other with the insertion space 1100i disposed therebetween, the support portion 1300 and the terminal 1600 may not be electrically connected to each other (short-circuited).

In other words, when the aerosol generating article 2 is not accommodated in the insertion space 1100i and is empty, even when voltage is applied to both ends of the detection unit 1500 through the control unit, the support portion 1300 and the terminal 1600 may be in an open state without being electrically connected to each other. In this case, current may not flow between the support portion 1300 and the terminal 1600.

As the aerosol generating article 2 is accommodated in the insertion space 1100i, each of the support portion 1300 and the terminal 1600 may contact the identifier 23 of the aerosol generating article 2. The support portion 1300 and the terminal 1600 may be electrically connected to each other through the aerosol generating article 2. Specifically, current may flow between the support portion 1300 and the terminal 1600 through the identifier 23 included in the aerosol generating article 2. Therefore, as the aerosol generating article 2 is accommodated in the insertion space 1100i, the value of current flowing through the support portion 1300 may change from 0 to a specific value.

According to the embodiment, a plurality of support portions 1300 may be disposed. In this case, the plurality of support portions 1300 may be spaced apart from each other at equal intervals in a circumferential direction of the insertion space 1100i.

As the plurality of support portions 1300 are disposed, the separate terminal 1600 may not be disposed. In this case, the support portion 1300 may serve as the terminal 1600. At least one pair of the plurality of support portions 1300 may be electrically connected to each other through the aerosol generating article 2 accommodated in the insertion space 1100i. Specifically, current may flow between a pair of support portions 1300 through the identifier 23 included in the aerosol generating article 2.

Referring to FIG. 8B, three support portions 1300 are spaced apart from each other at equal intervals inside the aerosol generating device 1. In this regard, a first support portion 1300-1 and a second support portion 1300-2 may be connected to both ends of the detection unit 1500. However, because the first support portion 1300-1 and the second support portion 1300-2 are spaced apart from each other with the insertion space 1100i disposed therebetween, the first support portion 1300-1 and the second support portion 1300-2 may be in an open state without being electrically connected to each other (short-circuited).

On the other hand, a third support portion 1300-3 may be connected to both ends of the detection unit 1500. In this case, a closed circuit may be formed between the detection unit 1500 and the third support portion 1300-3. Current may flow through the third support portion 1300-3 regardless of whether the aerosol generating article 2 is accommodated in the insertion space 1100i.

As the aerosol generating article 2 is accommodated in the insertion space 1100i, each of the first support portion 1300-1 and the second support portion 1300-2 may be in contact with the identifier 23 of the aerosol generating article 2. The first support portion 1300-1 and the second support portion 1300-2 may be electrically connected to each other through the aerosol generating article 2. Specifically, current may flow between the first support portion 1300-1 and the second support portion 1300-2 through the identifier 23 included in the aerosol generating article 2.

Likewise, the third support 1300-3 may also be in contact with the identifier 23 of the aerosol generating article 2. As the third support portion 1300-3 is electrically connected to the identifier 23, a value of current flowing through the third support portion 1300-3 may change.

In conclusion, as the aerosol generating article 2 is accommodated in the insertion space 1100i, the values of current flowing through the first support portion 1300-1 and the second support portion 1300-2 may change from 0 to a specific value, and the value of current flowing through the third support portion 1300-3 may also change from a preset value to a specific value.

Referring to FIG. 8C, four support portions 1300 are spaced apart from each other at equal intervals inside the aerosol generating device 1. In this regard, the first support portion 1300-1 and the second support portion 1300-2 may be connected to both ends of the detection unit 1500, respectively. In addition, the third support portion 1300-3 and a fourth support portion 1300-4 may be connected to both ends of the detection unit 1500, respectively. In this case, the first support portion 1300-1 and the second support portion 1300-2 may form a pair, and the third support portion 1300-3 and the fourth support portion 1300-4 may form another pair.

When the insertion space 1100i is empty, the first support portion 1300-1 and the second support portion 1300-2 may be in an open state without being electrically connected to each other (short-circuited). Likewise, the third support portion 1300-3 and the fourth support portion 1300-4 may be in an open state without being electrically connected to each other (short-circuited).

As the aerosol generating article 2 is accommodated in the insertion space 1100i, all the support portions 1300 may contact the identifier 23 of the aerosol generating article 2. The pair of the first support portion 1300-1 and the second support portion 1300-2 may be electrically connected to each other through the identifier 23 so that current may flow between the first support portion 1300-1 and the second support portion 1300-2. Likewise, the other pair of the third support portion 1300-3 and the fourth support portion 1300-4 are also electrically connected to each other through the identifier 23 so that current may flow between the third support portion 1300-3 and the fourth support portion 1300-4. In conclusion, as the aerosol generating article 2 is accommodated in the insertion space 1100i, the values of current flowing through all the support portions 1300 may change from 0 to specific values.

Meanwhile, according to the embodiment, voltage may be applied only to the first support portion 1300-1 and the second support portion 1300-2, and voltage may not be applied to the third support portion 1300-3 and the fourth support portion 1300-4. In this case, even when the aerosol generating article 2 is inserted so that the third support portion 1300-3 and the fourth support portion 1300-4 are in contact with the identifier 23, a closed circuit to which another internal component (e.g., the detection unit 1500) of the aerosol generating device 1, the third support portion 1300-3, and the fourth support portion 1300-4 are connected may not be formed.

In this regard, the third support portion 1300-3 and the fourth support portion 1300-4 may support the aerosol generating article 2, but may not be used to detect the change in the state of the insertion space 1100i based on the current. This is the same even though the third support portion 1300-3 and the fourth support portion 1300-4 are connected to the detection unit 1500.

Accordingly, a user may determine whether to apply voltage to the two support portions 1300 connected to both ends of the detection unit 1500, and use only a desired function among various functions of the detection unit 1500. As a result, the user may reduce unnecessary power consumption for himself/herself.

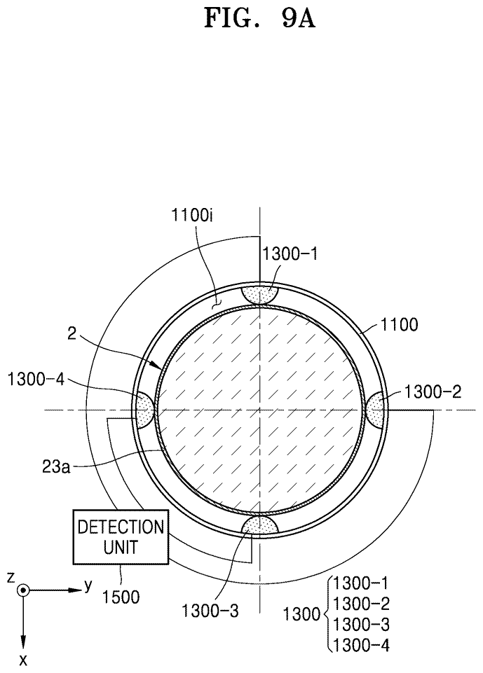

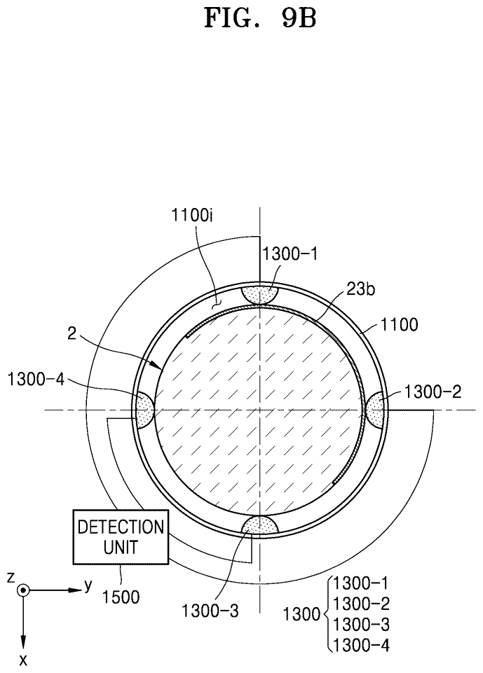

FIGS. 9A and 9B are cross-sectional views illustrating the aerosol generating article 2 with different lengths of identifiers 23a and 23b surrounding an outer circumferential surface of the aerosol generating article 2 inserted into the aerosol generating device 1 according to embodiments.

Referring to FIGS. 9A and 9B, the aerosol generating device 1 according to embodiments may include the housing 1100, the support portion 1300, and the detection unit 1500. Detailed descriptions of the configuration and effects of the aerosol generating device 1 which are redundant with those described above will be omitted.

In FIGS. 9A and 9B, four support portions 1300 are spaced apart from each other in a circumferential direction of the insertion space 1100i. The four support portions 1300 are connected to one detection unit 1500.

Before the aerosol generating article 2 is inserted into the insertion space 1100i, the four support portions 1300 each connected to the detection unit 1500 may not be connected to each other. In this case, even when voltage is applied by arbitrarily selecting two of the four support portions 1300, not only the other two support portions 1300 to which voltage is not applied, but also the two support portions 1300 to which voltage is applied may be in an electrically open state.

In FIGS. 9A and 9B, the aerosol generating article 2 is inserted into the insertion space 1100i. The identifiers 23a and 23b each surrounding at least a part of the outer circumferential surface of the aerosol generating article 2 are disposed in the aerosol generating article 2. In this regard, degrees to which the identifiers 23a and 23b surround the outer circumferential surface of the aerosol generating article 2 are different in each drawing.

Referring to FIG. 9A, the identifier 23a surrounds the outer circumferential surface by 360 degrees in a circumferential direction of the aerosol generating article 2. In this case, when the aerosol generating article 2 is accommodated in the insertion space 1100i, all the support portions 1300 may be in contact with the identifier 23a.

The support portions 1300 may be electrically connected to each other through the aerosol generating article 2 accommodated in the insertion space 1100i. Specifically, all the support portions 1300 may be electrically connected to each other through the identifier 23 included in the aerosol generating article 2 to allow current to flow therethrough.

In this case, even when voltage is applied by arbitrarily selecting two of the four support portions 1300, all support portions 1300 may be electrically connected to each other to allow current to flow therethrough. In this regard, because all support portions 1300 are electrically connected to the identifier 23a, values of current flowing through the support portions 1300 may be the same, but the embodiment is not limited thereto.

Referring to FIG. 9B, the identifier 23b surrounds a part of the outer circumferential surface of the aerosol generating article 2 in the circumferential direction. For example, the identifier 23b surrounds the outer circumferential surface of the aerosol generating article 2 by 180 degrees. In this regard, when the aerosol generating article 2 is accommodated in the insertion space 1100i, two adjacent support portions 1300 may contact the identifier 23b.

The two adjacent support portions 1300 may form a pair. The pair of support portions 1300 disposed adjacent to each other in the circumferential direction of the insertion space 1100i may be electrically connected to each other through the aerosol generating article 2 accommodated in the insertion space 1100i. Specifically, current may flow between the pair of support portions 1300 through the identifier 23b included in the aerosol generating article 2.

As shown, the identifier 23b is in contact with the first support portion 1300-1 and the second support portion 1300-2. In this case, when voltage is applied to the first support portion 1300-1 and the second support portion 1300-2, current may flow through the first support portion 1300-1 and the second support portion 1300-2 through the identifier 23b.

Meanwhile, because the support portion 1300 that is not in contact with the identifier 23b is in an electrically open state, current may not flow even when voltage is applied to the support portion 1300.

For example, even when voltage is applied to the third support portion 1300-3 and the fourth support portion 1300-4 that are not in contact with the identifier 23b and adjacent to each other, current may not flow because the third support portion 1300-3 and the fourth support portion 1300-4 are not electrically connected to each other through the identifier 23b. In this regard, even when the third support portion 1300-3 and the fourth support portion 1300-4 that are not in contact with the identifier 23b are respectively paired with the first support portion 1300-1 and the second support portion 1300-2 that are in contact with the identifier 23b, and voltage is applied to a pair of two support portions (e.g., the fourth support portion 1300-4 and the first support portion 1300-1), current may not flow because the fourth support portion 1300-4 and the first support portion 1300-1 are not connected to each other through the identifier 23b.

On the other hand, because the aerosol generating article 2 is not inserted in a constant direction, the two support portions 1300 with which the identifier 23b may be in contact may change whenever the aerosol generating article 2 is inserted.

In consideration of this, a control unit (e.g., the control unit 12 of FIG. 1) may determine whether the state of the insertion space 1100i changes by a control method of applying voltage to a pair of support portions (e.g., the second support portion 1300-2 and the third support portion 1300-3) disposed adjacent to each other through a power supply (e.g., the power supply 11 of FIG. 1), and when current does not flow therethrough, applying voltage to a next pair of support portions (e.g., the third support portion 1300-3 and the fourth support portion 1300-4) disposed adjacent to each other. When a pair of support portions (e.g., the first support portion 1300-1 and the second support portion 1300-2) through which current flows appear through the process, the control unit may determine that the aerosol generating article 2 has been inserted.

Meanwhile, according to the embodiment, current may flow through the support portion 1300 even when the support portion 1300 does not contact the identifier 23b. For example, current may flow through the support portion 1300 through a conductive material included in the aerosol generating article 2.

However, current may flow smoothly in a part where the identifier 23b is disposed with a relatively small electrical resistance compared to a part where the identifier 23b is not disposed. Therefore, when the two parts are connected to each other, current may flow only to the part where the identifier 23b is disposed. Therefore, it may be seen that a region in which the identifier 23b is disposed and a region in which the identifier 23b is not disposed are not electrically connected to each other.

For example, the first support portion 1300-1 and the second support portion 1300-2 may be electrically connected to each other through the identifier 23b so that current may flow through the first support portion 1300-1 and the second support portion 1300-2. The third support portion 1300-3 and the fourth support portion 1300-4 are electrically connected to each other through the conductive material included in the aerosol generating article 2 so that current may flow through the third support portion 1300-3 and the fourth support portion 1300-4.

However, in the case of the second support portion 1300-2 and the third support portion 1300-3, the second support portion 1300-2 is in contact with the identifier 23b, but the third support portion 1300-3 is not in contact with the identifier 23b. Because current flows to the part where the identifier 23b with a relatively small electrical resistance is disposed, the second support portion 1300-2 and the third support portion 1300-3 are not electrically connected to each other, so that current may not flow through the second support portion 1300-2 and the third support portion 1300-3.

In this regard, upon comparing the value of current flowing through the first support portion 1300-1 and the second support portion 1300-2 electrically connected to each other through the identifier 23b with the value of current flowing through the third support portion 1300-3 and the fourth support portion 1300-4 electrically connected to each other through the conductive material included in the aerosol generating article 2, the two values may be significantly different. Therefore, the control unit may distinguish between the value of current flowing through the identifier 23b and the value of current flowing through the conductive material included in the aerosol generating article 2.

For example, memory (e.g., the memory 17 of FIG. 1) embedded in the aerosol generating device 1 may store a range of the value of current flowing through the identifier 23b and a range of the value of current flowing through the conductive material included in the aerosol generating article 2, and the two ranges may not overlap.

Various factors may affect the change in the state of the insertion space 1100i (e.g., whether the aerosol generating article 2 is inserted, the type of aerosol generating article 2, and the state of the inserted aerosol generating article 2), and thus the control unit may make various determinations based on each of the two current values. In this regard, the two current values may be used to determine the same factor or may be used to determine different factors.

On the other hand, the number of support portions 1300 in contact with the identifier 23b may change according to the degree to which the identifier 23b surrounds the outer circumferential surface of the aerosol generating article 2. For example, when the degree to which the identifier 23b surrounds the aerosol generating article 2 is 90 degrees or more and less than 180 degrees, one to two support portions 1300 may contact the identifier 23b. When the degree to which the identifier 23b surrounds the aerosol generating article 2 is 180 degrees or more and less than 270 degrees, two to three support portions 1300 may contact the identifier 23b. In this regard, the number of support portions 1300 in contact with the identifier 23b may change according to a direction in which the support portion 1300 is inserted.

In this regard, the control unit may determine whether current flows through the support portion 1300 according to the process described above, and, when current flows, determine factors that may affect the change in the state of the insertion space 1100i, including whether the aerosol generating article 2 has been inserted based on the value of current flowing through the support portion 1300.

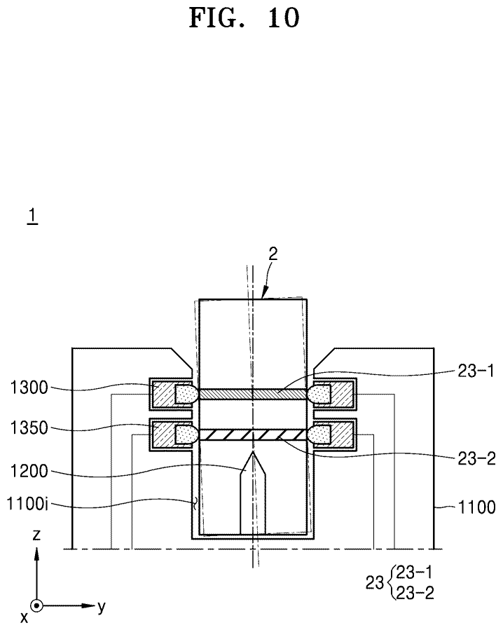

FIG. 10 is a cross-sectional view of the aerosol generating device 1 according to another embodiment to which a plurality of support portions 1300 disposed in a longitudinal direction of the insertion space 1100i are applied.

Referring to FIG. 10, the aerosol generating device 1 according to another embodiment may include the housing 1100, the heater 1200, a first portion 1300, and a second support portion 1350. Detailed descriptions of the configuration and effects of the aerosol generating device 1 which are redundant with those described above will be omitted.

As shown, the heater 1200 may be inserted into the aerosol generating article 2. In this regard, the heater 1200 inserted into the aerosol generating article 2 may be referred to as an ‘internal heating type heater’. The internal heating type heater 1200 may have a rod shape or a needle shape, but the embodiment is not limited to the described example.

When a center axis of the aerosol generating article 2 accommodated in the insertion space 1100i in the longitudinal direction and a center axis of the heater 1200 in the longitudinal direction are aligned in a line, the heater 1200 may be located in the center of the aerosol generating article 2 in a radial direction of the aerosol generating article 2. Accordingly, the heaters 1200 are spaced apart from all points of an outer circumferential surface of the aerosol generating article 2 by the same distance, and thus the aerosol generating article 2 may be uniformly heated.

However, when an inner diameter of the insertion space 1100i is larger than a diameter of the aerosol generating article 2, the center axis of the aerosol generating article 2 and the center axis of the heater 1200 may be misaligned while inserting the aerosol generating article 2.

For example, the center axis of the aerosol generating article 2 and the center axis of the heater 1200 may be disposed in parallel. This case may mean that the aerosol generating article 2 is inserted in the longitudinal direction (e.g., z-axis direction) of the insertion space 1100i, in a biased state in one direction rather than in the center of the insertion space 1100i.

As another example, the center axis of the aerosol generating article 2 and the center axis of the heater 1200 may intersect at one point or be disposed at a twisted position. This case may mean that the aerosol generating article 2 is not inserted in the longitudinal direction of the insertion space 1100i and is accommodated in the insertion space 1100i in an inclined state.

According to another embodiment, the plurality of first support portions 1300 disposed at equal intervals in the circumferential direction of the insertion space 1100i may guide the insertion of the aerosol generating article 2 such that the center axis of the aerosol generating article 2 and the center axis of the heater 1200 are aligned in a line.

In this regard, because the first support portion 1300 is in point contact with the outer circumferential surface of the aerosol generating article 2, despite the first support portion 1300 supporting the aerosol generating article 2, there is a possibility that the aerosol generating article 2 may be accommodated in an inclined state, as shown by the two-dot dashed line in FIG. 10.

In the case of the external heating type heater 1200 shown in FIG. 4, because the heater 1200 is disposed to surround the outer circumferential surface of the aerosol generating article 2, this problem is unlikely to occur because the heater 1200 may guide the insertion of the aerosol generating article 2, but in the case of the internal heating type heater 1200 shown in FIG. 10, this problem is highly likely to occur because the heater 1200 does not guide the insertion of the aerosol generating article 2.

In order to solve the problem described above, the aerosol generating device 1 according to another embodiment may include the second support portion 1350 spaced apart from the first support portion 1300 in the longitudinal direction of the insertion space 1100i. That is, the plurality of second support portions 1300 and 1350 may be spaced apart from each other in the longitudinal direction of the insertion space 1100i.

As shown, the second support portion 1350 is disposed below the first support portion 1300. In this regard, the first support portion 1300 and the second support portion 1350 may be aligned in a line in the longitudinal direction of the insertion space 1100i. However, according to the embodiment, the first support portion 1300 and the second support portion 1350 may be disposed at positions that are misaligned with each other. For example, the second support portion 1350 may be disposed in a lower portion of the first support portion 1300 in the longitudinal direction of the insertion space 1100i, and may be disposed between the two adjacent first support portions 1300 in the circumferential direction of the insertion space 1100i.

According to another embodiment, because the first support portion 1300 and the second support portion 1350 together support the aerosol generating article 2, the problem that the aerosol generating article 2 is accommodated in the inclined state due to the point contact with the first support portion 1300 may be prevented.

On the other hand, in the aerosol generating article 2, two identifiers 23 may be spaced apart from each other in the longitudinal direction of the aerosol generating article 2. For example, a first identifier 23-1 and a second identifier 23-2 surround the outer circumferential surface of the aerosol generating article 2 in the circumferential direction of the aerosol generating article 2.

In this regard, the plurality of support portions 1300 and 1350 may be disposed and include the first support portion 1300 in contact with the first identifier 23-1 and the second support portion 1350 in contact with the second identifier 23-2. The first support portion 1300 may contact the first identifier 23-1 at a first position, and the second support portion 1350 may contact the second identifier 23-2 at a second position.

As described above, because the first support portion 1300 and the second support portion 1350 are spaced apart from each other in the longitudinal direction of the insertion space 1100i, the second position may mean a position spaced apart from the first position in the longitudinal direction of the insertion space 1100i.

According to another embodiment, because the first identifier 23-1 and the second identifier 23-2 are spaced apart from each other, the plurality of first support portions 1300 in contact with the first identifier 23-1 and the plurality of second support portions 1350 in contact with the second identifier 23-2 may not be electrically connected to each other even when current flows therethrough.

Accordingly, values of current flowing through the first support portion 1300 and the second support portion 1350 may be different from each other, and accordingly, the first support portion 1300 and the second support portion 1350 may be used to determine different factors that may affect the change in the state of the insertion space 1100i.

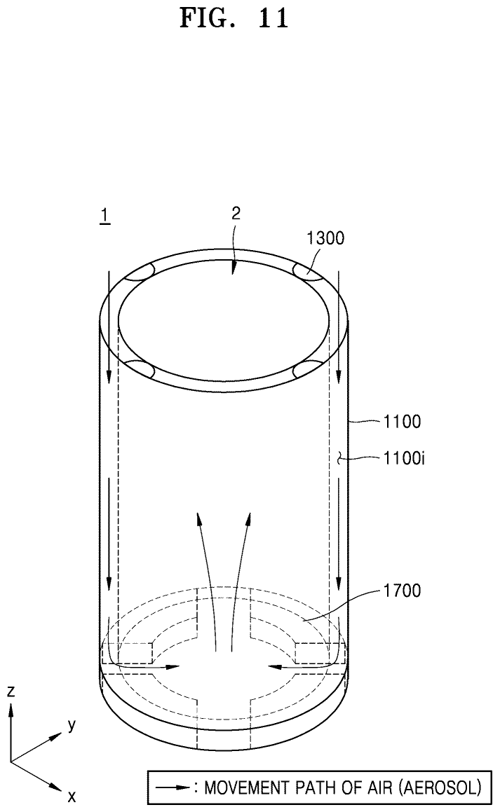

FIG. 11 is a cross-sectional perspective view illustrating the aerosol generating device 1 according to another embodiment in which an airflow passage is formed between the support portions 1300 disposed in a circumferential direction of the insertion space 1100i.

Referring to FIG. 11, the aerosol generating device 1 according to another embodiment may include the housing 1100, the support portion 1300, and a base portion 1700. Detailed descriptions of the configuration and effects of the aerosol generating device 1 which are redundant with those described above will be omitted. Meanwhile, the heater 1200 is omitted for convenience of description.

As shown, the aerosol generating article 2 is accommodated in the insertion space 1100i. The plurality of support portions 1300 may support an outer circumferential surface of the aerosol generating article 2.

As the support portion 1300 protrudes to the insertion space 1100i, the aerosol generating article 2 may be spaced apart from an inner wall of the housing 1100 surrounding the insertion space 1100i. Accordingly, a separation space may be formed between the inner wall of the housing 1100 and the aerosol generating article 2.

The separation space may also be located between the plurality of support portions 1300 disposed in the circumferential direction of the insertion space 1100i. In this regard, the separation space may be formed because at least a part of the support portion 1300 protrudes to the insertion space 1100i.

According to another embodiment, the separation space may be used as the airflow passage through which air moves. Air flowing from the outside of the aerosol generating device 1 may move toward a lower portion of the insertion space 1100i along the separation space that is the airflow passage. Accordingly, even though a separate airflow passage is not secured inside the aerosol generating device 1, the separation space formed by the arrangement of the support portion 1300 may be used as the airflow passage, and thus the manufacturing process of the aerosol generating device 1 may be simplified, and the limited space inside the aerosol generating device 1 may be used compactly.

On the other hand, the air that moves along the separation space and reaches the lower portion of the insertion space 1100i needs to flow into one end of the aerosol generating article 2. To this end, the aerosol generating device 1 according to another embodiment may include the base portion 1700.

The base portion 1700 is component that supports one end of the aerosol generating article 2, and separates one end of the aerosol generating article 2 from a bottom surface of the insertion space 1100i by a certain distance.

A plurality of support portions 1700 may be disposed. The plurality of support portions 1700 may be spaced apart from each other in the circumferential direction of the insertion space 1100i. Air may pass through the separated space.

The plurality of support portions 1700 may support one region of one end of the aerosol generating article 2. For example, the plurality of support portions 1700 may support the periphery of one end of the aerosol generating article 2. In this regard, the periphery of one end may mean a region from the edge of one end by a certain in an inward direction. Accordingly, the center of one end of the aerosol generating article 2 may be exposed to the insertion space 1100i to face the bottom surface of the insertion space 1100.

The air having passed through the space between the plurality of support portions 1700 may move to an empty space formed in the lower portion of the aerosol generating article 2. In this regard, the empty space formed in the lower portion of the aerosol generating article 2 may mean space formed by the aerosol generating article 2 being spaced apart from the bottom surface of the insertion space 1100i by the base portion 1700.

Air may flow into the center of one end of the aerosol generating article 2 that is exposed toward the bottom surface of the insertion space 1100i. The air flowing into the aerosol generating article 2 may be mixed with vaporized particles generated in the aerosol generating article 2 and inhaled by a user in the form of an aerosol.

Hereinafter, various factors that cause a change in a state of the insertion space 1100i and subsequent control operations of a control unit (e.g., the control unit 12 of FIG. 1) that detects the change in the state and determines the factors will be described.

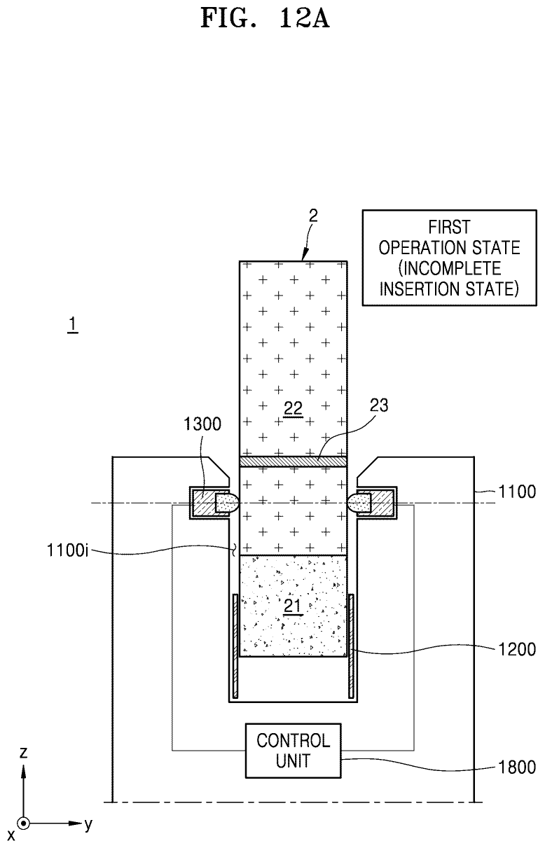

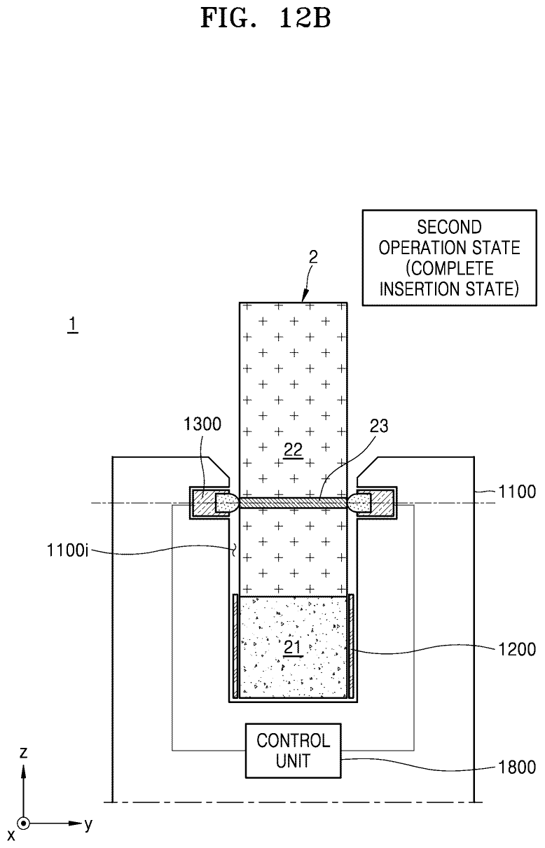

FIGS. 12A and 12B are cross-sectional views illustrating an operation state of the aerosol generating device 1 while the aerosol generating article 2 is inserted into the aerosol generating device 1 according to another embodiment.

Referring to FIGS. 12A and 12B, the aerosol generating device 1 according to another embodiment may include the housing 1100, the heater 1200, the support portion 1300, and a control unit 1800. Detailed descriptions of the configuration and effects of the aerosol generating device 1 which are redundant with those described above will be omitted.

In FIGS. 12A and 12B, a factor causing a change in a state of the insertion space 1100i may be the insertion of the aerosol generating article 2 into the insertion space 1100i. That is, the state of the insertion space 1100i may change according to whether the aerosol generating article 2 is inserted into or accommodated in the insertion space 1100i. In this regard, “whether the aerosol generating article 2 is inserted” and “whether the aerosol generating article 2 is accommodated” may indicated the same meaning and be used interchangeably below.

The control unit 1800, which is a component that controls the overall operation of the aerosol generating device 1, may correspond to the same component as the control unit (e.g., the control unit 12 of FIG. 1) described with reference to FIG. 1. The control unit 1800 may detect whether the aerosol generating article 2 is accommodated in the insertion space 1100i based on current flowing through the support portion 1300.

As shown, the control unit 1800 is directly connected to the support portion 1300, but according to the embodiment, a detection unit (not shown) may be connected to the support portion 1300, and the control unit 1800 may be connected to the detection unit to determine whether the aerosol generating article 2 is inserted through the detection unit. For example, when the detection unit generates a signal in response to a change in a value of current flowing through the support portion 1300, the control unit 1800 may determine whether the aerosol generating article 2 is inserted based on the signal generated by the detection unit.

Referring to FIG. 12A, the aerosol generating device 1 is in a first operation state where the aerosol generating article 2 is not completely inserted into the insertion space 1100i. In this regard, the first operation state may mean an incomplete insertion state of the aerosol generating article 2.

However, the first operation state is not limited to that illustrate, and may include all states from before the aerosol generating article 2 is inserted into the insertion space 1100i until the aerosol generating article 2 is completely inserted into the insertion space 1100i.

In the first operation state, voltage may be applied to the two support portions 1300. However, the two support portions 1300 are in an electrically open stated until the aerosol generating article 2 is completely inserted into the insertion space 1100i, so that current may not flow through the support portions 1300.

Based on the fact that current does not flow through the support portion 1300, the control unit 1800 may determine that the aerosol generating article 2 is not completely inserted into the insertion space 1100i, and may control the heater 1200 to be turned off by blocking power supplied to the heater 1200. In addition, the control unit 1800 may inform a user through an output unit (e.g., the output unit 14 of FIG. 1) that the aerosol generating article 2 is not completely inserted into the insertion space 1100i.

Referring to FIG. 12B, the aerosol generating device 1 is in a second operation state where the aerosol generating article 2 is completely inserted into the insertion space 1100i. In this regard, the second operation state may mean a state where the aerosol generating article 2 is completely inserted.

In the second operation state, the two support portions 1300 may be in contact with the identifier 23 disposed on an outer circumferential surface of the aerosol generating article 2. The two support portions 1300 may be electrically connected to each other through the identifier 23. Therefore, when voltage is applied to the two support portions 1300, current may flow through the two support portions 1300.

The control unit 1800 may determine that the aerosol generating article 2 is completely inserted into the insertion space 1100i based on the fact that current flows through the support portions 1300 through the identifier 23 in contact with the support portions 1300, and control the heater 1200 to be turned on by supplying power to the heater 1200. In addition, the control unit 1800 may inform the user through the output unit that the aerosol generating article 2 has been completely inserted into the insertion space 1100i.

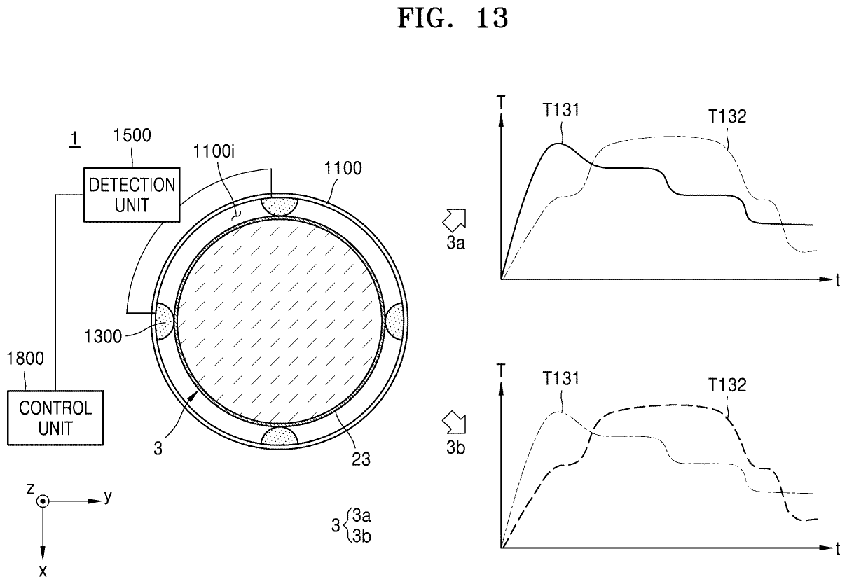

FIG. 13 is a diagram illustrating a heating profile that changes with the type of an aerosol generating article 3 inserted into the aerosol generating device 1 according to another embodiment.

Referring to FIG. 13, the aerosol generating device 1 according to another embodiment may include the housing 1100, the support portion 1300, the detection unit 1500, and the control unit 1800. Detailed descriptions of the configuration and effects of the aerosol generating device 1 which are redundant with those described above will be omitted.

In FIG. 13, a factor causing a change in a state of the insertion space 1100i may be the type of the aerosol generating article 3 inserted into the insertion space 1100i. That is, the state of the insertion space 1100i may change according to the type of the aerosol generating article 3 inserted into or accommodated in the insertion space 1100i.

A variety of types of aerosol generating articles 3 may be inserted into the aerosol generating device 1. In this regard, a different type of the aerosol generating article 3 may mean a different composition constituting an aerosol generating rod (e.g., the aerosol generating rod 21 of FIG. 4). That is, because the component of an aerosol generated in the aerosol generating rod changes with the type of the aerosol generating article 3, the taste of the aerosol inhaled by a user may change.

In this regard, because the aerosol generating rod is a portion heated by a heater (e.g., the heater 1200 of FIG. 4), the optimal heating profile may be different for each type of aerosol generating article 3. The aerosol generating article 3 may be heated with the optimal heating profile corresponding to the type of inserted aerosol generating article 3, and thus the user's smoking satisfaction may be improved.

The aerosol generating device 1 according to another embodiment may classify the type of aerosol generating article 3 accommodated in the insertion space 1100i and heat the aerosol generating article 3 with a heating profile corresponding thereto.

In this regard, the type of the aerosol generating article 3 may be distinguished by the identifier 23 surrounding an outer circumferential surface of the aerosol generating article 3. For example, a material or composition of the identifier 23 may change according to the type of the aerosol generating article 3.

When the support portion 1300 contacts the identifier 23 and current flows through the support portion 1300, a value of current flowing through the support portion 1300 may change according to the material or composition of the identifier 23. That is, the value of current flowing through the support portion 1300 may change according to the type of the aerosol generating article 3.

The control unit 1800 may detect the type of the aerosol generating article 3 inserted into the insertion space 1100i based on the current flowing through the support portion 1300. Specifically, when current flows through the support portion 1300 through the identifier 23 disposed on the outer circumferential surface of the aerosol generating article 3, the control unit 1800 may determine the type of aerosol generating article 3 based on the strength (value) of current flowing through the support portion 1300.

As shown, the support portion 1300 may be connected to the detection unit 1500, and the control unit 1800 may be connected to the detection unit 1500 to determine the type of the aerosol generating article 3 through the detection unit 1500. For example, when the detection unit 1500 generates different signals in response to the value of current flowing through the support portion 1300 or a variation in the value of current, the control unit 1800 may determine the type of aerosol generating article 3 based on the signals generated by the detection unit 1500.

However, according to the embodiment, the control unit 1800 may be directly connected to the support portion 1300 to determine the type of the aerosol generating article 3. In this case, the control unit 1800 may determine the type of the aerosol generating article 3 inserted into the insertion space 1100i based on the value of current flowing through the support portion 1300 or the variation in the value of current.

The control unit 1800 may control power to be supplied to a heater in response to the type of the aerosol generating article 3. Specifically, the control unit 1800 may control the heater to heat the aerosol generating article 3 with the optimal heating profile corresponding to the type of aerosol generating article 3 inserted into the insertion space 1100i. The type of the aerosol generating article 3 and the optimal heating profile corresponding thereto may be previously stored in memory (e.g., the memory 17 of FIG. 1).

For example, when the aerosol generating article 3 inserted into the insertion space 1100i is a first aerosol generating article 3a, the control unit 1800 may control the heater to heat the aerosol generating article 3a with a first heating profile T131.

As another example, when the aerosol generating article 3 inserted into the insertion space 1100i is a second aerosol generating article 3b, the control unit 1800 may control the heater to heat the aerosol generating article 3b with a second heating profile T132.

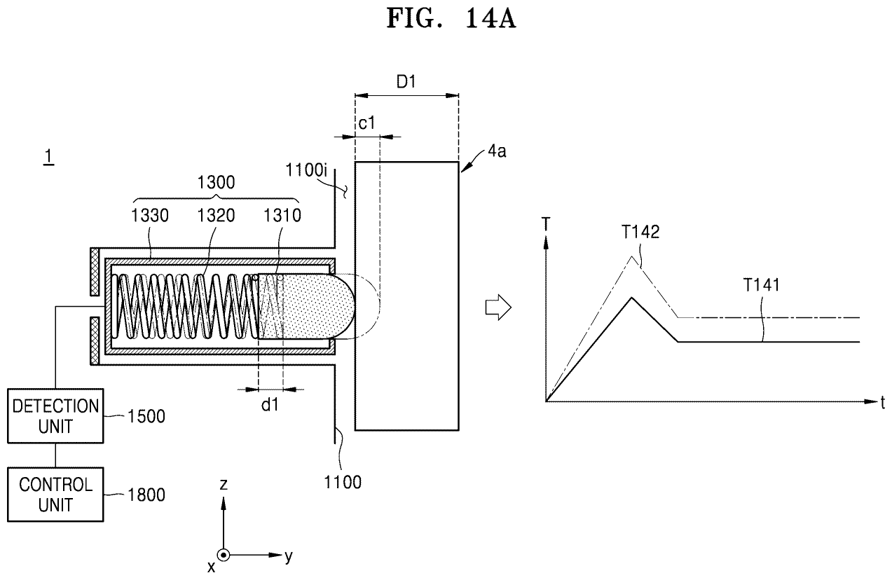

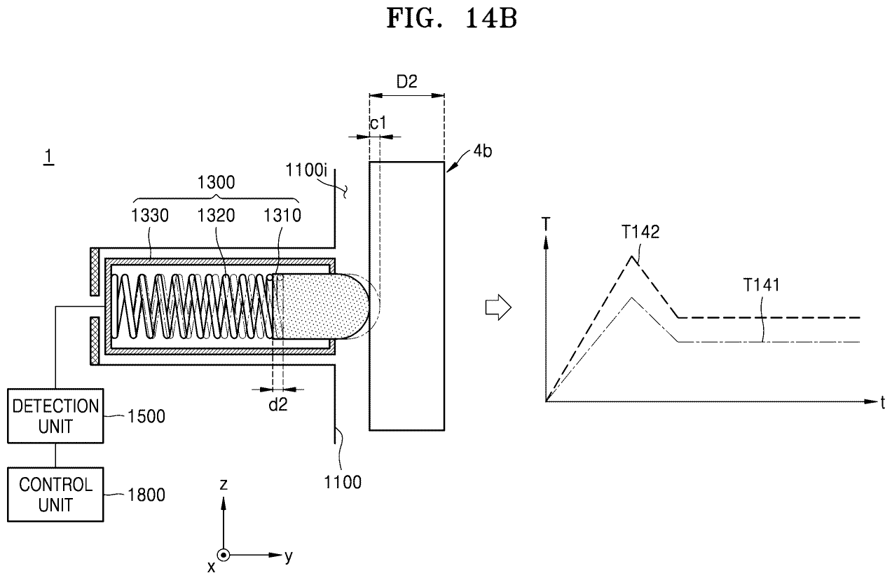

FIGS. 14A and 14B are diagrams respectively illustrating a first heating profile T141 and a second heating profile T142 that change according to a first diameter D1 and a second diameter D2 of aerosol generating articles 4a and 4b inserted into the aerosol generating device 1 according to another embodiment.

Referring to FIGS. 14A and 14B, the aerosol generating device 1 according to another embodiment may include the housing 1100, the support portion 1300, the detection unit 1500, and the control unit 1800. Detailed descriptions of the configuration and effects of the aerosol generating device 1 which are redundant with those described above will be omitted.

In FIGS. 14A and 14B, factors causing a change in a state of the insertion space 1100i may be the dimensions (e.g., diameters) of the aerosol generating articles 4a and 4b inserted into the insertion space 1100i. That is, the state of the insertion space 1100i may change according to the dimensions of the aerosol generating articles 4a and 4b inserted into or accommodated in the insertion space 1100i.

The aerosol generating device 1 according to another embodiment may heat the aerosol generating articles 4a and 4b by changing heating profiles according to the dimensions (e.g., diameters) of the aerosol generating articles 4a and 4b inserted into the insertion space 1100i.

When the aerosol generating articles 4a and 4b are inserted into the insertion space 1100i, the contact member 1310 of the support portion 1300 in contact with the aerosol generating articles 4a and 4b may move in a second direction (e.g., −y direction), and the elastic member 1320 connected to the contact member 1310 may be compressed in the second direction.

In this regard, the dimensions of the aerosol generating articles 4a and 4b inserted into the insertion space 1100i may affect the displacement of the contact member 1310 and the elastic member 1320 constituting the support portion 1300.

The detection unit 1500 may be disposed to measure the displacement of the elastic member 1320. For example, the detection unit 1500 may generate an electrical signal corresponding to the displacement of the elastic member 1320. Based on the electrical signal generated by the detection unit 1500, the control unit 1800 may determine the displacement of the elastic member 1320.

As another example, the detection unit 1500 may generate an electrical signal corresponding to a value of current flowing through the support portion 1300, on the assumption that the value of current flowing through the support portion 1300 may change according to the displacement of the elastic member 1320. Based on the electrical signal generated by the detection unit 1500, the control unit 1800 may determine the displacement of the elastic member 1320. According to an embodiment, the detection unit 1500 may be omitted. In this case, the control unit 1800 connected to the support portion 1300 may determine the displacement of the elastic member 1320 based on the value of current flowing through the support portion 1300.

As another example, the detection unit 1500 may measure the displacement of the elastic member 1320 and transmit a measured value to the control unit 1800. In this case, the control unit 1800 may use the measured value provided by the detection unit 1500 without separately determining the displacement of the elastic member 1320.

When the elastic member 1320 is compressed in the second direction by the aerosol generating articles 4a and 4b accommodated in the insertion space 1100i, the control unit 1800 electrically connected to the detection unit 1500 may control power to be supplied to a heater (e.g., the heater 1200 of FIG. 4) based on the displacement of the elastic member 1320.

In this case, the control unit 1800 may control the heater to heat the aerosol generating articles 4a and 4b by changing the heating profile according to the displacement of the elastic member 1320. In this regard, the displacement of the elastic member 1320 and the heating profile corresponding thereto may be previously stored in memory (e.g., the memory 17 of FIG. 1).

Referring to FIG. 14A, when the first aerosol generating article 4a with the first diameter D1 is inserted into the insertion space 1100i, the contact member 1310 may move by a first distance c1 in the second direction from the original position, and accordingly, the elastic member 1320 may be compressed by a first length d1 from the original length while being compressed in the second direction.

In this regard, the original position and the original length may mean a position of the contact member 1310 and a length of the elastic member 1320 when the support portion 1300 maximally protrudes to the insertion space 1100i because the support portion 1300 does not contact the aerosol generating articles 4a and 4b.

The control unit 1800 may control the heater to heat the first aerosol generating article 4a with the first heating profile T141 based on a displacement d1 of the elastic member 1320 according to the insertion of the first aerosol generating article 4a.

Referring to FIG. 14B, when the second aerosol generating article 4b with the second diameter D2 smaller than the first diameter D1 is inserted into the insertion space 1100i, the contact member 1310 may move by a second distance c2 from the original position in the second direction, and accordingly, the elastic member 1320 may be compressed by a second length d2 from the original length while being compressed in the second direction.

The control unit 1800 may control the heater to heat the second aerosol generating article 4b with the second heating profile T142 based on a displacement d2 of the elastic member 1320 according to the insertion of the second aerosol generating article 4b.

According to another embodiment, the temperature of the second heating profile T142 may be higher than the temperature of the first heating profile T141. That is, the control unit 1800 may control the heater to heat the second aerosol generating article 4b to a higher temperature than the first aerosol generating article 4a. This is because the diameter D2 of the second aerosol generating article 4b is smaller than the diameter D1 of the first aerosol generating article 4a.

Specifically, when an external heating type heater is employed in the aerosol generating device 1, the external heating type heater may surround the aerosol generating articles 4a and 4b and heat the aerosol generating articles 4a and 4b. In this regard, the smaller the diameters D1 and D2 of the aerosol generating articles 4a and 4b, the greater the distances by which outer circumferential surfaces of the aerosol generating articles 4a and 4b are spaced apart from an inner surface of the external heating type heater. Therefore, heat generated by the heater may not be sufficiently transferred to the aerosol generating articles 4a and 4b. To compensate for this, the control unit 1800 may increase the heating temperature of the heater such that the aerosol generating articles 4a and 4b with the small diameters D1 and D2 may be sufficiently heated.

However, the embodiment is not limited to increasing the heating temperature of the heater as the diameters D1 and D2 of the aerosol generating articles 4a and 4b are smaller. For example, because the greater the diameters D1 and D2 of the aerosol generating articles 4a and 4b, the larger the volume that needs to be heated by the heater, the control unit 1800 may control the heater to heat the aerosol generating articles 4a and 4b to a higher temperature in consideration of this.

Meanwhile, according to the description above, the control unit 1800 differently controls a heating profile of the heater according to the displacement of the elastic member 1320, and according to the embodiment, the control unit 1800 may control the heater based on the movement distance or displacement of the contact member 1310. In this case, the detection unit 1500 may be disposed to measure the movement distance or displacement of the contact member 1310.

In addition, according to the description above, the dimensions (e.g., diameters) of the aerosol generating articles 4a and 4b are not measured and determined by the control unit 1800, but according to the embodiment, the control unit 1800 may measure and determine the dimensions of the aerosol generating articles 4a and 4b through the detection unit 1500.

In this case, the dimensions of the aerosol generating articles 4a and 4b may be determined based on the displacement of the elastic member 1320, or measured by the detection unit 1500 regardless of the displacement of the elastic member 1320. The control unit 1800 may control the heater to heat the aerosol generating articles 4a and 4b with heating profiles corresponding to the dimensions of the aerosol generating articles 4a and 4b.

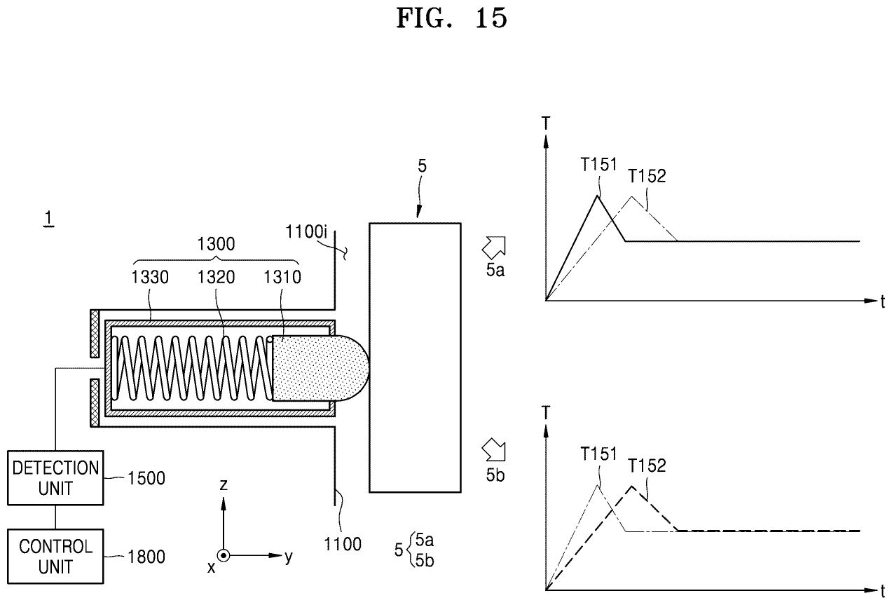

FIG. 15 is a diagram illustrating a heating profile that changes with a state of an aerosol generating article 5 inserted into the aerosol generating device 1 according to another embodiment.

Referring to FIG. 15, the aerosol generating device 1 according to another embodiment may include the housing 1100, the support portion 1300, the detection unit 1500, and the control unit 1800. Detailed descriptions of the configuration and effects of the aerosol generating device 1 which are redundant with those described above will be omitted.

In FIG. 15, a factor causing a change in a state of the insertion space 1100i may be the state of the aerosol generating article 5 inserted into the insertion space 1100i. That is, the state of the insertion space 1100i may change according to the state of the aerosol generating article 5 inserted into or accommodated in the insertion space 1100i.

The aerosol generating device 1 according to another embodiment may determine the state of the aerosol generating article 5 accommodated in the insertion space 1100i. As an example, the aerosol generating device 1 may determine the moisture content of the aerosol generating article 5.

According to another embodiment, the support portion 1300 may be a probe for measuring the moisture content of the aerosol generating article 5. In this regard, it is assumed that current may flow through the support portion 1300 even when the aerosol generating article 5 is not inserted into the insertion space 1100i. In addition, it is assumed that even though the support portion 1300 does not contact an identifier (not shown) disposed on an outer circumferential surface of the aerosol generating article 5, when the support portion 1300 contacts the outer circumferential surface of the aerosol generating article 5, current may flow through the support portion 1300.

According to another embodiment, the moisture content of the aerosol generating article 5 may be determined by the capacitance of the insertion space 1100i. The detection unit 1500 connected to the support portion 1300 may generate an electrical signal according to a change in the capacitance of the insertion space 1100i through the support portion 1300 exposed to the insertion space 1100i.

In this regard, the detection unit 1500 may have the same component as the overly moist sensor described with reference to FIG. 1. That is, the detection unit 1500 may be used to determine whether the aerosol generating article 5 accommodated in the insertion space 1100i is overmoistured. “Overmoisture” may mean a state where the moisture content of the aerosol generating article 5 is higher than a preset value or range.

The control unit 1800 may read a changing value of capacitance by accommodating the aerosol generating article 5 in the insertion space 1100i by using the detection unit 1500. The value of capacitance may change according to whether the aerosol generating article 5 is accommodated in the insertion space 1100i, and change according to the moisture content of the aerosol generating article 5.

In this regard, a value of current flowing through the support portion 1300 may change according to whether the aerosol generating article 5 is accommodated in the insertion space 1100i and the moisture content of the aerosol generating article 5, similar to the value of capacitance of the insertion space 1100i. That is, the value of current flowing through the support portion 1300 may correspond to the value of capacitance of the insertion space 1100i.

The detection unit 1500 may generate a signal corresponding to a change in the capacitance of the insertion space 1100i based on a change in the value of current flowing through the support portion 1300. For example, when the value of capacitance satisfies a preset condition, the detection unit 1500 may generate a specific signal. In this regard, the ‘preset condition’ may mean various conditions such as the value of capacitance being correspond to a value within a preset range or exceed a preset threshold value.

The control unit 1800 electrically connected to the detection unit 1500 may continuously read the value of capacitance in response to a change in the value of capacitance of the insertion space 1100i or the aerosol generating article 5 over time by using the detection unit 1500.

The control unit 1800 may determine the moisture content of the aerosol generating article 5 and whether the aerosol generating article 5 is overmoistured based on the specific signal generated by the detection unit 1500. Specifically, the control unit 1800 determine the moisture content of the aerosol generating article 5 and whether the aerosol generating article 5 is overmoistured based on the changing value of capacitance corresponding to the state of the insertion space 1100i (e.g., the state (moisture content) of the aerosol generating article 5 accommodated in the insertion space 1100i).

When it is determined that the aerosol generating article 5 is overmoistured, the control unit 1800 may control a heater to heat the aerosol generating article 5 for a certain time. In this regard, the “certain time” may mean a time sufficient for the moisture content of the aerosol generating article 5 to be reduced below a preset value by heating the aerosol generating article 5.

For example, assuming that the moisture content of the aerosol generating article 5a in a first state is a normal moisture content that is not determined to be overmoistured, and that the moisture content of the aerosol generating article 5b in a second state is a moisture content that is determined to be overmoistured, the control unit 1800 may heat the aerosol generating article 5a in the first state to a first heating profile T151 and the aerosol generating article 5b in the second state to a second heating profile T152.

In this regard, when heating the aerosol generating article 5 with the second heating profile T152, the heater may heat the aerosol generating article 5 for a long time compared to heating the aerosol generating article 5 with the first heating profile T151. That is, the heater may heat the aerosol generating article 5 for a time sufficient for the moisture content of the aerosol generating article 5 to be reduced below the preset value.

According to another embodiment, in the case of the aerosol generating article 5b that is overmoistured, the temperature of the aerosol inhaled by the user may be adjusted to an appropriate temperature for the user to inhale, and thus the user may experience satisfactory smoking.

In addition, the control unit 1800 may provide a notification that the user may recognize through an output unit (e.g., output unit 14 of FIG. 1) such that the user does not inhale the aerosol for a certain time while the moisture content of the aerosol generating article 5 is reduced.

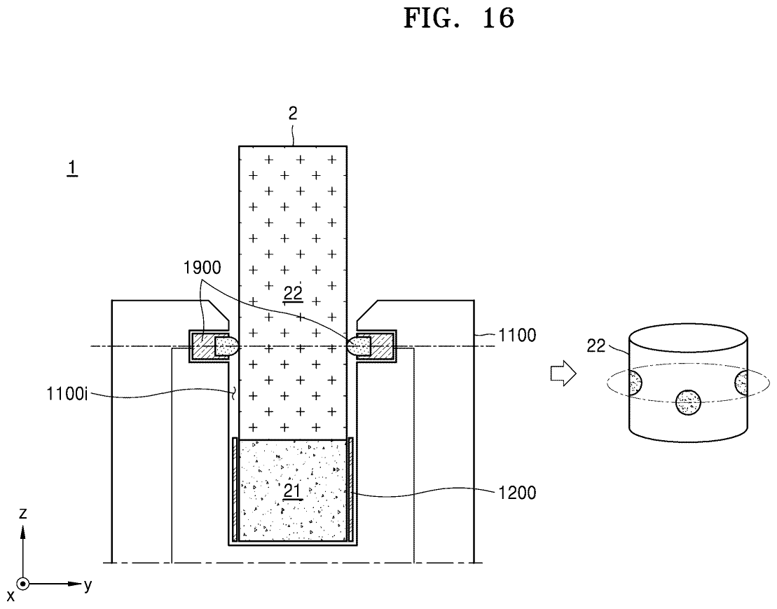

FIG. 16 is a diagram illustrating the aerosol generating device 1 according to another embodiment to which a heating support portion 1900 is applied and a filter rod 22 of the aerosol generating article 2 heated by the heating support portion 1900.

Referring to FIG. 16, the aerosol generating device 1 according to another embodiment may include the housing 1100, the heater 1200, and the heating support portion 1900. Detailed descriptions of the configuration and effects of the aerosol generating device 1 which are redundant with those described above will be omitted.

The heating support portion 1900 may support an outer circumferential surface of the filter rod 22 of the aerosol generating article 2 accommodated in the insertion space 1100i and simultaneously heat the outer circumferential surface of the filter rod 22.

As shown on the right of the aerosol generating device 1, as the heat generating support portion 1900 generates heat, a trace of heating may remain on a part of the filter rod 22 in contact with the heat generating support portion 1900.

According to the embodiment, when the non-heating type aerosol generating device 1 is used, the separate heater 1200 is not disposed in the aerosol generating device 1, and accordingly, no trace of heating remains on the aerosol generating article 2. In this case, whether the aerosol generating article 2 is used is not be visually determined, which causes a problem that the once-used aerosol generating article 2 may be reused.

According to another embodiment, because the trace of heating remains on the filter rod 22 by the heating support portion 1900, a user may check whether the aerosol generating article 2 is used by looking at the trace of heating.

In addition, the heating support portion 1900 may expand a void formed inside the filter rod 22 by heating the filter rod 22. Accordingly, an aerosol may move smoothly through the expanded void, thereby reducing inhalation resistance felt when the user inhales the aerosol.

In addition, when there is a flavoring agent inside the filter rod 22, the flavoring agent may be heated by the heating support portion 1900. Accordingly, the generation of flavor from the flavoring agent and the transition of flavor to the end of the mouse may be promoted. The user may experience a rich flavor while inhaling the aerosol.

According to the aerosol generating device according to the embodiments, the aerosol generating article may be appropriately supported or fixed by the support portion regardless of the deviation of the inserted aerosol generating article.

In addition, according to the aerosol generating device according to the embodiments, the airflow passage may be secured around the aerosol generating article by the support portion protruding to the insertion space.

In addition, according to the aerosol generating device according to the embodiments, various functions may be performed using current flowing through the support portion and the aerosol generating article, and thus, the ease of use of the aerosol generating device may be improved.

An aerosol generating device according to an embodiment may include a housing including an insertion space accommodating an aerosol generating article, a heater configured to heat the aerosol generating article accommodated in the insertion space, and one or more support portions disposed in an upper portion of the heater, at least partially movable in a first direction facing the insertion space or in a second direction away from the insertion space, and configured to support the aerosol generating article disposed the insertion space, and a value of current flowing through the one or more support portions may change in response to a change in a state of the insertion space.

In an example, each of the one or more support portions may include a contact member configured to support an outer circumferential surface of the aerosol generating article accommodated in the insertion space and an elastic member configured to press the contact member in the first direction when compressed in the second direction.

In an example, the contact member may include a contact part including a curved surface in contact with the aerosol generating article and a non-contact part extending from the contact part in the second direction.

In another example, the contact member may include a first contact part including an inclined surface inclined relative to a longitudinal direction of the insertion space, a second contact part disposed to face the aerosol generating article accommodated in the insertion space, and a non-contact part extending from one end of the first contact part in the second direction.

In an example, the aerosol generating device may further include a detection unit configured to measure a displacement of the elastic member and a control unit electrically connected to the detection unit, when the elastic member is compressed in the second direction by the aerosol generating article accommodated in the insertion space, the control unit may control power to be supplied to the heater based on the displacement of the elastic member.

In an example, the aerosol generating device may further include a terminal having at least a part exposed to the insertion space and disposed to face at least one of the one or more support portions, and the terminal may be electrically connected to the one or more support portions through the aerosol generating article accommodated in the insertion space.

In another example, the support portion may be disposed in plural, the plurality of support portions may be spaced apart from each other at equal intervals in a circumferential direction of the insertion space, and at least one pair of the plurality of support portions may be electrically connected to each other through the aerosol generating article accommodated in the insertion space.

In this case, a pair of support portions disposed adjacent to each other in the circumferential direction of the insertion space may be electrically connected to each other through the aerosol generating article accommodated in the insertion space.

In another example, the support portion may be disposed in plural, and the plurality of support portions may be spaced apart from each other in a longitudinal direction of the insertion space.

In this case, the plurality of support portions may include a first support portion in contact with a first identifier of the aerosol generating article at a first position and a second support portion in contact with a second identifier of the aerosol generating article at a second position spaced apart from the first position in the longitudinal direction of the insertion space.

In an example, the one or more support portions may protrude in the insertion space to separate the aerosol generating article from an inner wall of the housing surrounding the insertion space, and a separation space formed between the inner wall of the housing and the aerosol generating article may be an airflow passage through which air moves.

In an example, the aerosol generating device may further include a control unit configured to detect whether the aerosol generating article has been accommodated in the insertion space based on the current flowing through the one or more support portions, when the current flows through the one or more support portions through an identifier disposed on an outer circumferential surface of the aerosol generating article, the control unit may determine that the aerosol generating article has been completely inserted into the insertion space and control power to be supplied to the heater.

In an example, the aerosol generating device may further include a control unit configured to detect a type of the aerosol generating article inserted into the insertion space based on the current flowing through the one or more support portions, when the current flows through the one or more support portions through an identifier disposed on an outer circumferential surface of the aerosol generating article, the control unit may determine the type of the aerosol generating article based on intensity of the current flowing through the support portion and control power to be supplied to the heater in response to the type of the aerosol generating article.

In an example, the aerosol generating device may further include a detection unit configured to detect a change in capacitance of the insertion space through the one or more support portions exposed to the insertion space and a control unit electrically connected to the detection unit, the control unit may determine whether the aerosol generating article is overmoistured based on a value of the capacitance that changes in response to a state of the aerosol generating article accommodated in the insertion space, and control the heater to heat the aerosol generating article for a certain time when it is determined that the aerosol generating article is overmoistured.

In an example, the one or more support portions may generate heat to heat an outer circumferential surface of a filter rod of the aerosol generating article accommodated in the insertion space.

Certain embodiments or other embodiments of the present disclosure described above are not exclusive or distinct from each other. The certain embodiments or other embodiments of the present disclosure described above may be combined with each other or used in combination with each other in their respective components or functions.

For example, it means that an A component described in a specific embodiment and/or the drawings and a B component described in another embodiment and/or the drawings may be combined with each other. In other words, even when it is not explained directly about combination between components, it is possible to combine unless it is explained that combination is impossible.

The above detailed description should not be interpreted restrictedly but should be considered illustrative in all aspects. The scope of the present disclosure should be determined by a rational interpretation of the attached claims, and all changes within the equivalent scope of the present disclosure are included in the scope of the present disclosure.

According to the aerosol generating device according to the embodiments, an aerosol generating article may be appropriately supported or fixed by a support portion regardless of a deviation of the inserted aerosol generating article.

In addition, according to the aerosol generating device according to the embodiments, various functions may be performed using current flowing through the support portion and the aerosol generating article, and thus, the ease of use of the aerosol generating device may be improved.

Effects of the present disclosure are not limited to the above effects, and effects that are not mentioned could be clearly understood by one of ordinary skill in the art from the present specification and the attached drawings.

What is claimed is:

1. An aerosol generating device comprising:
a housing comprising an insertion space accommodating an aerosol generating article;
a heater configured to heat the aerosol generating article accommodated in the insertion space; and
one or more support portions disposed in an upper portion of the heater, at least partially movable in a first direction facing the insertion space or in a second direction away from the insertion space, and configured to support the aerosol generating article disposed the insertion space,
wherein a value of current flowing through the one or more support portions change in response to a change in a state of the insertion space.

2. The aerosol generating device of claim 1, wherein
wherein each of the one or more support portions includes
a contact member configured to support an outer circumferential surface of the aerosol generating article accommodated in the insertion space; and
an elastic member configured to press the contact member in the first direction when compressed in the second direction.

3. The aerosol generating device of claim 2, wherein the contact member includes a contact part including a curved surface in contact with the aerosol generating article and a non-contact part extending from the contact part in the second direction.

4. The aerosol generating device of claim 2, wherein the contact member includes a first contact part including an inclined surface inclined relative to a longitudinal direction of the insertion space, a second contact part disposed to face the aerosol generating article accommodated in the insertion space, and a non-contact part extending from one end of the first contact part in the second direction.

5. The aerosol generating device of claim 2, further comprising:
a detection unit configured to measure a displacement of the elastic member; and
a control unit electrically connected to the detection unit,
wherein when the elastic member is compressed in the second direction by the aerosol generating article accommodated in the insertion space, the control unit is configured to control power to be supplied to the heater based on the displacement of the elastic member.

6. The aerosol generating device of claim 1, further comprising: a terminal having at least a part exposed to the insertion space and disposed to face at least one of the one or more support portions,
wherein the terminal is electrically connected to the one or more support portions through the aerosol generating article accommodated in the insertion space.

7. The aerosol generating device of claim 1, wherein
the one or more support portions are disposed in plural,
the plurality of support portions are spaced apart from each other at equal intervals in a circumferential direction of the insertion space, and
at least one pair of support portions of the plurality of support portions is electrically connected to each other through the aerosol generating article accommodated in the insertion space.

8. The aerosol generating device of claim 7, wherein at least one pair of support portions disposed adjacent to each other in the circumferential direction of the insertion space are electrically connected to each other through the aerosol generating article accommodated in the insertion space.

9. The aerosol generating device of claim 1, wherein
the one or more support portions are disposed in plural, and
the plurality of support portions are spaced apart from each other in a longitudinal direction of the insertion space.

10. The aerosol generating device of claim 9, wherein the plurality of support portions include a first support portion in contact with a first identifier of the aerosol generating article at a first position and a second support portion in contact with a second identifier of the aerosol generating article at a second position spaced apart from the first position in the longitudinal direction of the insertion space.

11. The aerosol generating device of claim 1, wherein
the one or more support portions protrude in the insertion space to separate the aerosol generating article from an inner wall of the housing surrounding the insertion space, and
a separation space formed between the inner wall of the housing and the aerosol generating article is an airflow passage through which air moves.

12. The aerosol generating device of claim 1, further comprising: a control unit configured to detect whether the aerosol generating article has been accommodated in the insertion space based on the current flowing through the one or more support portions,
wherein, when the current flows through the one or more support portions through an identifier disposed on an outer circumferential surface of the aerosol generating article, the control unit is configured to determine that the aerosol generating article has been completely inserted into the insertion space and control power to be supplied to the heater.

13. The aerosol generating device of claim 1, further comprising: a control unit configured to detect a type of the aerosol generating article inserted into the insertion space based on the current flowing through the one or more support portions,
wherein when the current flows through the one or more support portions through an identifier disposed on an outer circumferential surface of the aerosol generating article, the control unit is configured to determine the type of the aerosol generating article based on intensity of the current flowing through the support portion and control power to be supplied to the heater in response to the type of the aerosol generating article.

14. The aerosol generating device of claim 1, further comprising:
a detection unit configured to detect a change in capacitance of the insertion space through the one or more support portions exposed to the insertion space; and
a control unit electrically connected to the detection unit,
wherein the control unit is configured to determine whether the aerosol generating article is overmoistured based on a value of the capacitance that changes in response to a state of the aerosol generating article accommodated in the insertion space, and control the heater to heat the aerosol generating article for a certain time when it is determined that the aerosol generating article is overmoistured.

15. The aerosol generating device of claim 1, wherein the one or more support portions are configured to generate heat to heat an outer circumferential surface of a filter rod of the aerosol generating article accommodated in the insertion space.
